(19) United States
(12) Patent Application Publication
(10) Pub. No.: US 2016/0148965 A1
(43) Pub. Date: May 26, 2016

(54) Detector assembly using vertical wire bonds and compression decals

(71) Applicant: James E. Clayton, Raleigh, NC (US)

(72) Inventor: James E. Clayton, Raleigh, NC (US)

(21) Appl. No.: 14/756,679

(22) Filed: Sep. 29, 2015

Related U.S. Application Data
(60) Provisional application No. 62/071,702, filed on Sep. 30, 2014.

(51) Int. Cl. H01L 27/146

(52) U.S. Cl. CPC H01L 27/14634; H01L 27/14658

(57) ABSTRACT

An imaging sensor includes a first monolithic semiconductor plate having an upper surface and a lower surface; a substantially continuous cathode deposited on the upper surface; an array of anode pads on the lower surface, each anode pad defining an individual pixel; a readout device having an array of readout pads on its upper surface, each readout pad corresponding to a respective anode pad and alignable therewith; and, a plurality of parallel, vertical wire bonds interconnecting the semiconductor plate and the readout device, with each wire connecting one anode pad to its respective readout pad.

### CROSS-REFERENCE TO RELATED APPLICATION

This application claims the benefit of Provisional Application Ser. No. 62/071,702, filed by the present inventor on Sep. 30, 2014, the entire disclosure of which is incorporated herein by reference.

### BACKGROUND OF THE INVENTION

1. Field of the Invention

The present invention relates generally to the field of semiconductor device assembly and packaging.

More particularly, the invention relates to the assembly and packaging of acoustic, neutron, and X-ray and Gamma-ray imaging detectors mounted onto substrates or ASIC readout IC chips.

2. Description of Related Art

A variety of different compliant, vertical, interconnect contacts, formed with gold or copper wires using a wire bonding process, have been previously disclosed in the literature. Examples include the WireSpring™ contacts developed and patented by FormFactor Inc. (U.S. Pat. No. 5,829,129) for probe cards used for contacting individual die or wafers during electrical functional testing, and compliant contact pins used for testing and/or burn-in of unpackaged (bare) die in the manufacture of known good die (KGD) patented by Micron Technology, Inc. (U.S. Pat. No. 5,495,667). In these two examples, the contact pins or vertical wires are bent or folded during the wire bonding process to impart a degree of resilient flexing or spring-like characteristics to the contacts. FormFactor, for instance, uses a plating process to deposit metal coatings over the surfaces of gold or copper wire bonds, in combination with forming of the wires, to provide the resiliency preferred for repeated mating and un-mating of contacts to multiple devices during burn-in testing or wafer probing. These types of vertical wire springs or compliant contact pins are intended mainly for temporary contact with the pads of the device under test. FormFactor Inc. however, did adapt their WireSpring™ contacts on Silicon Technology (MOST) for wafer level packaging, where the WireSpring contacts are used for first-level interconnections of semiconductor devices to various substrates, but the technology has not achieved widespread usage due to the serial nature of the process steps, the large number of process steps required, and the inability to achieve fine pitch interconnects [for background, see Integrated Interconnect Technologies for 3D Nanoelectronic Systems, James D. Meindl, page 64].

Other types of vertical wire bonds have been developed for vertical stacking or assembly of components where the wires are intended for a pin-in-socket type connection. The Flying Lead is an example, which was developed and patented by Cray Computer Corporation (U.S. Pat. No. 5,195,237) for attaching integrated circuits with gold vertical wire bonds directly into the through-plated holes of a circuit board.

Kulicke and Soffa, a manufacturer of gold and copper wire bonding equipment used by the semiconductor industry, has considerable experience in the development of unique wire bonding configurations. Two vertical wire bonding techniques developed by K&S are of particular interest for possible semiconductor assembly. The first process is known as a Free Air Ball wire bond and was developed for enabling microscopic examination and measurement of the Free Air Ball (FAB) formed at the tip of the capillary immediately prior to the ball being thermosonic bonded onto the pad of a semiconductor or substrate device at the beginning of a standard looped wire bond. Essentially, K&S developed a technique where the FAB is inverted and attached by a freestanding length of wire to the surface of an IC chip or substrate in an array to enable the diameters of the individual FABs to be measured using automated inspection equipment. Consistent and uniform FAB formation is important for achieving high wire bonding yields, which are produced at machine gun speeds during production. K&S offered the software to produce these vertical bonds as a premium upgrade for several years, before including it for new equipment purchases, together with other wire forming options, beginning about two years ago. It is important to note that the structure illustrated in FIG. 5 was not intended to serve any electrical function whatsoever. It is used solely to arrange a representative sample of FABs for visual inspection and statistical analysis

Unfortunately, the wire forming process used to create the K&S freestanding FABs requires multiple steps, described below, that are difficult to control with sufficient alignment and height uniformity for the contacts to be practical for assembling devices with small pitches between adjacent anode pads. In addition, the freestanding FAB bonded wires lean off-center from the pads to which the base of the wires are wedge-bonded. Preferably, the wires should extend vertically straight above the pads to which the base of the leads are bonded. [As used herein, “vertical” is defined as the direction normal to the surface of the device on which the wire bond is formed.]

A couple of years ago, K&S undertook to develop a new wire forming and bonding program for their wire bonding equipment, including their IConn™ wire bonder, to place a vertical wire bond extending vertically, straight above the pads. K&S originally termed the resulting wire bond as a “Stick Bond”, but later changed the term to a “Vertical Bond”. This program and wire forming process was developed for Invensas Corporation's patented Bond Via Array™ (BVA®) Package-on-Package (PoP) technology.

The wire forming process steps for achieving this particular “Vertical Bond” are described in detail below, but are summarized as follows: The FAB at the end of the capillary, formed by the Electronic Flame Off (EFO) wand, is thermosonic ball bonded to a pad on the surface of a substrate, then wire is paid out as the capillary rises vertically and loops the wire over a distance to contact the surface of the same substrate. A force is applied to the capillary, but little or no ultrasonic energy is used, to cause the wire to be crimped by the edge of the capillary tip at a pre-determined distance from the ball bond. A clamp above the capillary closes to hold the wire fast while the wire is pulled back into vertical alignment with the ball bond on the pad. The clamp opens as a short portion of wire is paid out to form the next FAB, but then closes to clamp the wire as it is pulled and breaks at the point of the indentation in the wire formed during the crimping process. The resulting Vertical Bond is a straight, freestanding wire which terminates with a pointed tip at the end of the wire.

Invensas Corporation has developed and patented (U.S. Pat. No. 8,772,152) a process for then encapsulating the freestanding wires, which are typically bonded around the perimeter of a substrate, with a molded dielectric material suitable for subsequent solder reflow assembly. The tips of the wires are partially embedded in a soft protective film during the molding process to enable the ends of the wires to be exposed before soldering the tips to another package in a vertical stack. The molding material otherwise completely encapsulates the wires to prevent them from being accidentally moved out-of-alignment during handling or subsequent assembly.

Although the wire forming technique developed by K&S for the new “Vertical Bond” provides a straight, freestanding wire with uniform height and accurate alignment, useful for the Bond Via Array™ (BVA®) Package-on-Package (PoP) technology developed at Invensas, these combined processes or technologies lack several attributes desired for the assembly of sensors or detectors to substrates or ASIC readout devices, including the following:
1. Because the vertical wires terminate with a sharp point, the wire tips are likely to damage the thin-film metal anode pads.
2. Some sensors and detectors used for X-ray and Gamma-ray imaging applications must be operated at a low temperature. Therefore it is desirable to minimize the transfer of heat from an active ASIC chip beneath the detector. Using an underfill epoxy or dielectric molding material to fill the void space between the adjoining surfaces of the ASIC chip and detector will increases the coupling of heat from the ASIC chip into the detector. Therefore, it is desirable that the freestanding vertical wire bonds remain un-encapsulated. This also allows cooled air or a suitable liquid to be circulated between the surfaces.

Many sensors and detectors are mated directly to an ASIC readout chip that is only slightly larger than the detector. The pixel readout pads on the ASIC chip are purposely designed with a pad pitch that matches the pitch of the anode pads arrayed on the detector, to enable a direct electrical connection between the corresponding pads. Therefore, almost the entire surface of the ASIC chip consists of an array of pixel readout pads. However, as described above, the wire forming process developed by K&S requires that the wire be “crimped” against the surface to which the wires are being bonded. This is not a limitation for the substrates and peripheral bond pads typical for package-on-package assembly. But the surface of an ASIC readout chip may consist of very delicate low-K dielectric material or passivation, or use traces with “air bridge” structures immediately below the surface, which are easily damaged from the force of the capillary tip. If the required crimping process is performed on another surface other than the ASIC chip, the wires may be too long in length to be practical, especially for the pixel pads within the center area of the chip. Likewise, the other adjacent pixel pads may be at the wrong pitch for crimping the wire to the desired length. Therefore, it is necessary either to somehow protect the surface of the ASIC chip during the wire forming process as currently developed by K&S, or to develop an entirely new wire forming process that does not require crimping the wire against the surface.

Sensors and detectors used for many X-ray and Gamma-ray applications are very expensive. They typically contain a monolithic slab of a semiconductor crystal such as CdTe or CdZnTe (CZT). These crystals are costly to prepare but cannot be easily removed and reworked with the presence of an underfill epoxy between the surfaces. However, an underfill epoxy is typically required to improve the reliability of the interconnections when a significant difference of coefficient of thermal expansion (CTE) exists between the materials being electrically joined. Without an underfill epoxy, the connections may fail by fatigue or stress during temperature cycling. Increasing the distance between the surfaces with large CTE mismatch and using a compliant material to join the surfaces, also helps to mitigate this problem. Therefore, it is desirable and preferred to use gold wires, rather than copper, for forming vertical wire bond connections that are of sufficient height to decouple the CTE mismatch of the joined materials, eliminating the necessity for using an underfill epoxy, and to simplify the removal of expensive detectors by simply cutting or shearing the array of interconnected thin gold wires.

In many applications for imaging pixel sensors or detectors, it is desirable that the gap between abutted edges of separate imaging devices within an array be kept to a minimum in order that the pixel pitch remains uniform or fixed across separate but adjoining detectors. Considerable thought goes into designing movable carriers, on which the detector and ASIC readout chip are mounted, that are adjusted to compensate for variability in the placement or positioning of several parts stacked together to form an assembled module. It is therefore very desirable if the positioning accuracy of the detector, placed at the top of the stacked module, can be repositioned after final assembly without requiring the expense and weight of an adjustable carrier. The “Vertical Bond”, as developed by K&S may be suitable for this purpose, but not if the wires terminate as sharp points that might easily be pulled loose from within a surrounding electrically conductive epoxy bump, or if the wires are encapsulated within a dielectric molding material, or if the wires are formed from copper, which may be too stiff to properly bend or move during the repositioning process. Therefore, un-encapsulated gold vertical wire bonds of sufficient length to enable the assembled detector to be mechanically moved into final alignment are preferred.

### OBJECTS AND ADVANTAGES

Objects of the invention include the following:

Replacing pin and socket connections to a motherboard with a removable, conformable, low-profile compression decal. Enabling room-temperature, flip chip assembly of a device to a substrate, interposer or ASIC device using a UV-cured, Anisotropic Conductive Adhesive through optically opaque surfaces. Enabling vertical wire bonds to be formed on a fragile surface of an ASIC device, where the wire must be looped and crimped with the tip of the bonding capillary against the surface of the IC being wire bonded. Reducing the number of wire bonding steps to form a vertical wire bond. Improving mechanical adhesion of vertical wire bonds within conductive epoxy or solder bumps. Elevating the detector or sensor from the surface of the substrate or ASIC readout device to reduce parasitic capacitance due to close coupling of the metal fields and traces on the adjoining surfaces. Decoupling the thermal expansion differences between the detector and the substrate or ASIC readout chip, eliminating the necessity for an underfill epoxy between the joined surfaces. Enabling cool air or a cooling liquid to circulate between a detector or sensor and its mating ASIC chip or substrate while increasing the thermal impedance between the two devices so that the detector may be kept at a lower temperature than the ASIC readout chip or substrate to which it is electrically and mechanically coupled. Simplifying removal of expensive detectors for rework and reuse on other substrates. Enabling detectors to be manipulated closer together to maintain uniform pixel pitches across tiled detectors and provide shock absorption. Enabling assembly of detectors of different thickness to align with coplanar Cathode surfaces. Enabling tiled detectors to overlap at their edges to maintain uniform pixel pitch. Enabling detector assemblies to be easily removed from within a large array of tiled detector assemblies. Enabling bent or misaligned vertical wire bonds to be re-straightened before assembly to a sensor or detector device: Enabling a detector module assembly to be mated to a motherboard by means of a removable, conformable, low-profile compression decal. Enabling large arrays of detector modules to be mated to a flexible circuit motherboard by means of removable, conformable, low-profile compression decals, so the large arrays of detector modules are easily removable and able to be folded into an arch, circle, right-angle or square. Enabling a smaller ASIC readout chip to be coupled to a larger sensor or detector by means of a chip carrier which is mated to a PCB or flexible circuit motherboard by means of a removable, conformable, low-profile compression decal. These and other objects and advantages of the invention will become apparent from consideration of the following specification, read in conjunction with the drawings.

### SUMMARY OF THE INVENTION

According to one aspect of the invention, an imaging sensor comprises:

a first monolithic semiconductor plate having an upper surface and a lower surface;

a substantially continuous cathode deposited on the upper surface;

an array of anode pads on the lower surface, each anode pad defining an individual pixel;

a readout device having an array of readout pads on its upper surface, each readout pad corresponding to a respective anode pad and alignable therewith; and,

a plurality of parallel, vertical wire bonds interconnecting the semiconductor plate and the readout device, with each wire connecting one anode pad to its respective readout pad.

According to another aspect of the invention, a method for making straight vertical wire bonds with free air balls comprises of the steps of:

forming a free air ball at the end of a wire protruding from the tip of a wire bonding capillary;

forming a conventional thermosonic ball bond to attach the free air ball to a pad on a circuit;

raising the capillary vertically straight above the ball bond while the wire pays out to a selected height;

clamping the wire and simultaneously cutting the wire and melting both of the cut ends, to form a second and third free air ball on the ends of the cut wire.

According to another aspect of the invention, a method for making vertical wire bonds with free air balls comprises the steps of:

forming a first free air ball at the end of a wire protruding from the tip of a wire bonding capillary;

forming a conventional thermosonic ball bond to attach the free air ball to a pad on a circuit;

raising the capillary vertically straight above the ball bond while the wire pays out to a selected height;

clamping the wire and weakening the wire at a point at a selected height;

applying tension to the wire straight above the ball bond until the wire breaks at the weakened point on the wire;

moving the capillary tip clear of the formed vertical wire;

forming a second free air ball by heating the broken end of the wire protruding from the tip of the capillary using an electronic flame off wand;

releasing the clamp and applying tension to draw the wire back into the capillary until the second free air ball is seated against the tip of the capillary;

moving the capillary tip close to the broken end of the vertical wire bond so that the electronic flame off wand is positioned to discharge a high voltage and low current from the EFO wand across an air gap to the tip of the vertical wire bond to form a third free air ball, while simultaneously contacting the base of the vertical wire bond with a shunt to protect the circuit pad from the voltage applied by the EFO wand to the tip of the wire.

According to another aspect of the invention, a method for making a compression decal comprises of the steps of:

forming a flexible dielectric film having a first surface and a second surface, and having a patterned array of via holes therebetween;

depositing conductive adhesive bumps on the first surface, directly over the via holes;

curing the bumps on the first side;

depositing conductive adhesive bumps on the second surface, directly over the via holes, and filling the via holes to establish electrical continuity through the vias;

curing the bumps on the second surface.

applying adhesive dots to at least one of the surfaces.

According to another aspect of the invention, a method for making a compression decal comprises of the steps of:

forming a patterned array of conductive metal pads on a first surface of a single-sided, copper-clad, flexible dielectric film;

forming open windows through the flexible dielectric film to expose a center portion of each of said pads, thereby making each of said pads accessible from the second surface of the film;

thermosonic bonding metal ball/stud bumps to a center portion of each of the pads exposed through the open windows in the flexible film, causing dimpled conductive bumps to form on the first surface of the flexible circuit and protruding tips of the metal ball/stud bumps on the second surface of the flexible circuit.

According to another aspect of the invention, a method for making a compression decal comprises the steps of:

forming a patterned array of open windows completely through the thickness of a flexible dielectric film;

laminating a copper sheet to a first surface of the flexible film;

etching the copper sheet to form a patterned array of pads on the first surface, with each pad centered respectively over one of the array of open windows in the flexible film;

thermosonic bonding metal ball/stud bumps to a center portion of each of the pads exposed through the open windows in the flexible film, causing dimpled conductive bumps to form on the first surface of the flexible circuit and protruding tips of the metal ball/stud bumps on the second surface of the flexible circuit.

According to another aspect of the invention, a method for interconnecting the anode pads of an imaging sensor to the readout pads of a readout device, comprises of the steps of:

aligning said imaging sensor with said readout device so that each anode pad is directly above its respective readout pad;

applying a coating of a UV curable anisotropic conductive adhesive between said anode pads and said readout pads, said anisotropic conductive adhesive containing electrically conductive particles and further containing at least one phosphor capable of producing light of a desired wavelength by a down-converting interaction with X-ray photons;

applying a compressive force between said sensor and said readout device;

exposing said adhesive to X-rays of sufficient intensity to cause said phosphors to generate sufficient UV light to photo-initiate the curing of said adhesive.

According to another aspect of the invention, a method for forming an area array of straight vertical wire bonds on the readout pads of an ASIC chip comprises the steps of:

a) applying a photoresist layer to the surface of an ASIC readout device;

b) baking the photoresist to a selected level of dryness;

c) selectively exposing the photoresist to UV light through a patterned photomask to selectively alter the solubility of the photoresist over each pixel readout pad;

d) developing the photoresist by immersion in a developing solution to expose the pixel readout pads through openings in the remaining photoresist surrounding said readout pads;

e) rinsing and drying the ASIC readout device;

f) baking the photoresist at a sufficient temperature to harden the photoresist;

g) attaching a metal ball bond to an ASIC pixel pad by a thermosonic bonding process and extending a length of wire therefrom;

h) looping the wire and crimping the wire at a selected distance from the ball bond against the surface of the hardened photoresist;

i) pulling the wire directly above the ball bond until the wire breaks at the crimped location on the wire; and,

j) repeating steps g-l for each of the pixel readout pads.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting embodiments illustrated in the drawing figures, wherein like numerals (if they occur in more than one view) designate the same elements. The features in the drawings are not necessarily drawn to scale.

FIGS. 1A-1C illustrate a typical pixelated imaging detector in three views; the Cathode or top view, FIG. 1A, a side profile view, FIG. 1B, and the Anode or bottom view, FIG. 1C.

FIGS. 2A-2F illustrate six cross sectional views of existing and prior art hybridization techniques for mating pixel-array detectors to a substrate or ASIC readout IC device. FIG. 2A shows a detector that includes indium metal bumps; FIG. 2B is very similar to FIG. 2A with exception that the indium bumps are replaced with solder alloy balls or bumps; FIG. 2C illustrates another prior art hybridization technique; FIG. 2D illustrates another prior art hybridization technique; in FIG. 2E, small gold or copper ball/stud bumps are pre-bonded to the pads of the substrate or ASIC readout IC; FIG. 2F illustrates yet another prior art hybridization technique.

FIGS. 3A-3D illustrate cross sectional views of two differing electrically conductive compression decals, FIGS. 3A and 3C, and two cross section views of how they are aligned and compressed between the anode pads of an imaging detector and contact pads of a substrate or ASIC readout chip, FIGS. 3B and 3D, according to one aspect of the invention.

FIG. 4 illustrates a cross sectional view of an imaging detector with an improved electrically conductive, UV-cured, ACA paste that is photo-initiated using high energy X-ray photons to electrically and mechanically connect the anode pads to the contact pads of an opaque substrate interposer.

FIG. 5 illustrates an example of prior art consisting of a linear array of leaning vertical wire bonds, formed from gold or copper wire and terminated with Free Air Balls (FABs), which are thermosonic bonded to a substrate for optical evaluation.

FIGS. 6A-6H illustrate a prior art process, consisting of six steps, for forming and attaching the leaning vertical wire bonds of FIG. 5 using a wire bonding machine: in FIG. 6A, the capillary moves upward; in FIG. 6B an arc is stuck to the end of the wire; in FIG. 6C, a FAB has been formed on the wire; in FIG. 6D, the wire is extended into a hole in a wire forming tool; in FIG. 6E, the wire is bent at 90°; in FIG. 6F, the wire is further bent upward; in FIG. 6B, the wire is bonded to the substrate; and in FIG. 6F, the capillary moves upward to break the wire.

FIGS. 7A-7H illustrate a “modified” prior art process, consisting of eight steps, for forming and attaching a straight vertical wire bond without a FAB at the end of the wire, using a wire bonding machine. In FIG. 7A, wire is extended from capillary; in FIGS. 7B and 7C an arc forms a ball on the wire; in FIG. 7D, ball is sonically bonded to substrate; in FIG. 7E, wire is extended; in FIG. 7F, the capillary applies pressure to crimp wire; in FIG. 7G, capillary moves upward to pay out additional wire; and in FIG. 7H, wire is clamped and capillary continues moving upward to break the wire.

FIGS. 8A-8B illustrate an improved process for protecting the surface of sensitive devices using a layer of photoresist, FIG. 8A, when attaching “modified” straight vertical wire bonds using the process steps detailed in FIG. 7. An example of a detector assembled to a substrate or ASIC readout chip using “modified” straight wire bonds, is also shown as FIG. 8B.

FIGS. 9A-9D illustrate an improved wire bonding process using only four steps for forming a preferred straight vertical wire bond with FAB. FIG. 9A shows a FAB on the end of the wire at capillary tip; FIG. 9B shows the capillary bonding wire to substrate; in FIG. 9C, wire is extended and an arc is struck; and in FIG. 9D, two FABs have been formed and capillary is raised.

FIG. 10 illustrates an array of straight vertical wire bonds with FABs thermosonic bonded to the pixel readout pads of a substrate or ASIC readout device.

FIG. 11 illustrates a preferred assembly of a sensor or detector onto a substrate or ASIC readout chip that includes the inventive vertical wire bonds with FABs shown in FIG. 10.

FIGS. 12A-12G illustrate alternative steps for fabricating straight vertical wire bonds with and without terminating FABs. FIG. 12A shows a wire with FAB at the end of capillary; FIG. 12B shows FAB being sonically bonded to substrate; FIG. 12C shows an arc cutting or weakening the wire; FIG. 12D shows an alternate version in which wire is mechanically crimped in situ; FIG. 12E shows the capillary moving upward to break wire; FIG. 12F shows an arc forming a new FAB on the out end of wire; and FIG. 12G shows arc forming a new FAB on the cut end of the bonded wire.

FIG. 13 shows a finished detector made according to one aspect of the invention, along with two variations thereof. FIGS. 13A-13B illustrate a preferred assembly similar to that shown in FIG. 11, of a sensor or detector flip chip bonded using ICA adhesive or solder paste bumps, to an array of straight vertical wire bonds with FABs attached to a substrate or ASIC readout chip. Examples with longer or shorter length vertical wire bonds are also shown, to enable overlapping the edges of the detectors, FIG. 13A, or adjusting for differences in detector thickness, FIG. 13B.

FIG. 14 illustrates a method and tool for straightening bent or misaligned vertical wire bonds.

FIG. 15 illustrates one example of a removable sensor or detector assembly with corner compression posts, mated to a PCB motherboard by means of a compression decal.

FIG. 16 illustrates another example of a removable sensor or detector assembly with a center compression post, mated to a PCB motherboard by means of a compression decal or pointed contacts.

FIG. 17 illustrates the same example of a removable detector assembly as described in FIG. 16, mated to a flexible circuit motherboard by means of a compression decal or pointed contacts and rigid stiffener plate.

FIG. 18 shows multiple removable detector assemblies, as described in FIG. 16, interconnected on a flexible circuit motherboard that is folded into an arch.

FIG. 19 shows multiple removable detector assemblies, as described in FIG. 16, interconnected on a flexible circuit motherboard that is folded into a right angle.

FIG. 20 illustrates another example of a removable sensor or detector assembly mated with a chip carrier holding an ASIC readout chip or other IC device that is smaller than the sensor or detector.

### DETAILED DESCRIPTION OF THE INVENTION

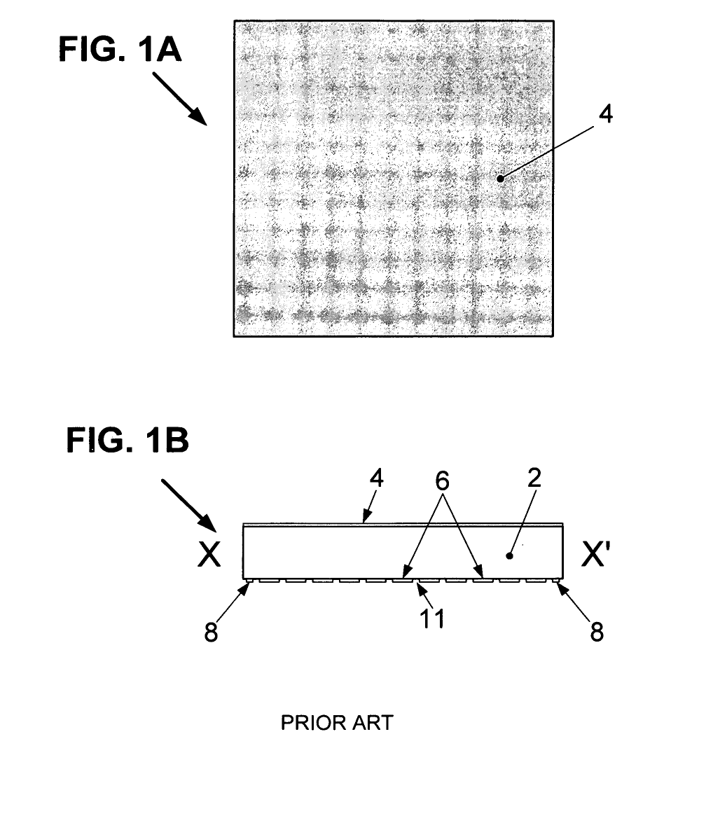

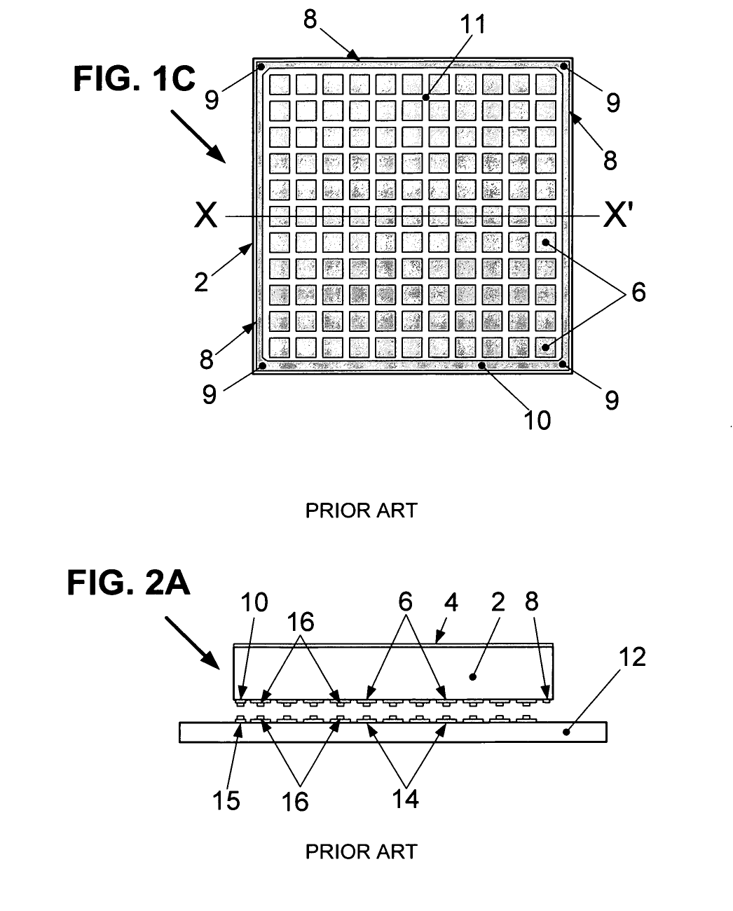

FIGS. 1A-1C illustrate a typical pixelated detector 2 in three views. FIG. 1A shows the Top or Cathode surface 4 of the detector. Pixel detectors are typically square in shape, but may also be rectangular as viewed from the top. The Cathode surface typically extends to the very edges of the detector, as represented in FIG. 1A, and consists of thin deposited metals such as gold, platinum, indium and other metals. The metal may be deposited by thin film sputtering or evaporation of the metal coating in a vacuum chamber or by electro-plating or electroless-plating of the metal onto the surface(s) by immersing the detector into a metal plating solution.

FIG. 1B illustrates a cross section view of the detector across a centerline X-X′ that includes a peripheral guard ring 8, anode pixel pads 6 and the inter-pixel gaps 11 that lay between individual pixel pads and the peripheral guard ring. For illustration purposes, the thickness of the Cathode and Anode metal pads and guard ring are exaggerated in this view. Actual thickness is typically in the nanometer range. The thickness of the bulk detector itself generally ranges from 0.5 mm for a silicon-diode or IR (infrared) detector to as much as 15 mm for a CZT detector. CZT detectors are commonly cut and polished in 1 mm, 2 mm, 3 mm and 5 mm thicknesses, while CdTe detectors are 1 mm or 2 mm thick. Newer detectors are currently being developed using Thallium-Bromide (TIBr) compositions.

FIG. 1C illustrates the Bottom or Anode surface of the detector. The individual anode pixel pads 6 are typically square in shape and arrayed as a cluster across the surface of the square detector. As shown in this example, the anode pixel pads 6 are symmetrically arrayed in an 11×11 grid pattern. Surrounding the anode pixel pads is a narrow, continuous, peripheral metal guard ring 8 that extends almost to the edges of the detector. The guard ring is typically biased at ground potential to help reduce surface current near the edge pixels. Electrical connection between the pad(s) of the substrate or ASIC readout device and the detector guard ring is often facilitated by wider contact pads 9 fashioned at the corners of the detector or a wider contact ribbon or strip 10 along one edge of the detector. The guard ring is typically separated from the outermost anode pixel pads (edge pixels) by a distance equal to the width of the inter-pixel gaps. The width of the inter-pixel gap is typically 25% of the width of the anode pixel pads. The thin metal anode pixel pads and guard ring are patterned on the bottom surface of the detector using a variety of methods, as is well known in the art. Similar to the deposition of the Cathode surface as described earlier, the thin metal can be deposited as a continuous film across the bottom surface by vacuum or plating deposition followed by an etching process to selectively remove the inter-pixel metal using photolithography techniques that are well known in the art. Alternatively, an array of anode pixel pads and guard ring can be patterned onto the surface of the detector using a developed photoresist mask prior to vacuum depositing or immersion plating the thin metal film. The photoresist is then later removed using a “lift-off” technique to produce the finished metal pattern. Alternatively, the thin metal anode pads (but not typically the guard ring, unless it extends to the very edges of the detector) may be deposited through a stainless steel “shadow mask” that overlays the anode surface of the detector during vacuum thin film deposition. Another alternative method that may be used to pattern the anode pixel pads and guard ring is to screen print a conductive metal paste or ink across the bottom surface of the detector. In the future it may be feasible to ink-jet print either the photoresist or metal anode pads.

Another type of detector (not shown) is known as a Stripe Detector and differs from the preceding description on both the cathode and anode surfaces. The cathode comprises a series of independently-biased parallel strips and the anode contacts are arranged in parallel rows perpendicular to the cathode strips.

Discussion of Prior Art

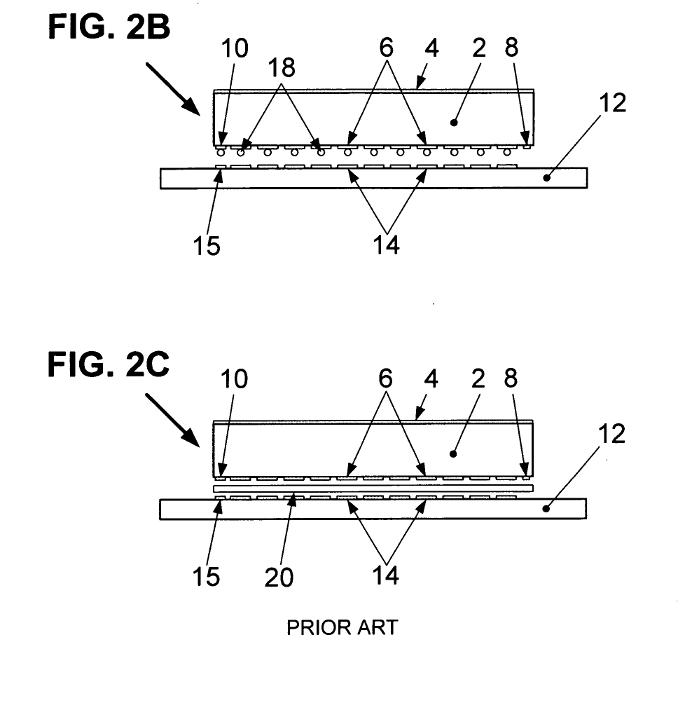

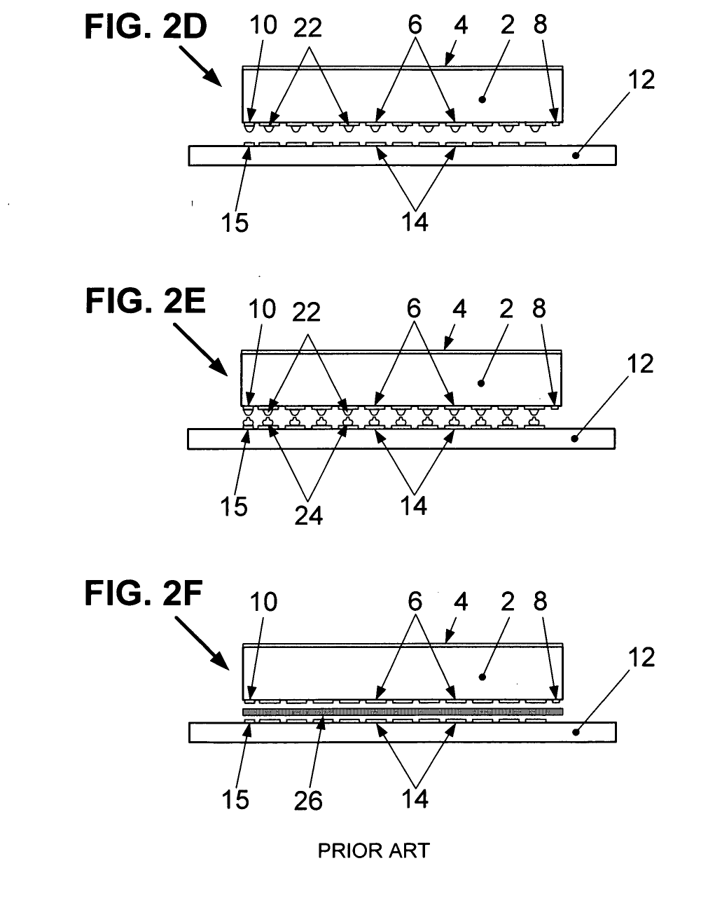

FIGS. 2A-2F illustrate cross section views of present and prior art hybridization techniques for mating pixel-array detectors to a substrate or ASIC readout device. The terms hybridization and bump bonding are used herein as synonyms that describe the technique or process for electrically and mechanically mating the anode surface of the detector to a rigid or flexible substrate or interposer fashioned from ceramic, metal, glass, laminated glass Printed Circuit Board (PCB), polyimide Kapton™ film, silicon, GaAs, SiC and other materials that are well known within the art of electronic component assembly, by means of Flip Chip (FC) technology or Surface Mount Technology (SMT). Each of the aforementioned materials may be substituted for and are included in the description for the. Substrate or ASIC readout device 12.

FIG. 2A shows a detector 2 that includes indium metal bumps 16, which are spaced apart directly above a substrate or ASIC readout device 12 that also includes readout pads 14 with indium metal bumps 16. The anode pixel pads 6, with indium bumps 16, of the detector, are aligned in both their X and Y-axis pitch with the indium bumps 16 on the substrate or ASIC readout pads 14. Although the X and Y-axis pitch of the pixel readout pads 14 are typically (though not always) identical to the X and Y-axis pitch of the detector's anode pads 6, the readout pads 14 are commonly smaller in size than the corresponding anode pads 6 on the detector. For illustration purposes the readout pads 14 are drawn at the same scale as the detector anode pads 6 in each of the views for FIGS. 2A-2F.

As shown in the cross section view of FIG. 2A, small indium metal bumps 16 are directly deposited onto the detector anode pads 6, the detector guard ring contact ribbon 10, the substrate or ASIC readout pads 14 and the substrate or ASIC guard ring contact pad 15. It should be noted that of the cross section portion of the guard ring 8 of detector 2, as shown in FIG. 2A, does not include an indium bump 16, whereas the wider guard ring contact ribbon 10 does include an indium bump. Since the guard ring is typically a continuous loop of metal around the periphery of the detector, it is common to include only a few electrical ground connections between the guard ring and the substrate or ASIC readout device. However, indium bumps are sufficiently small that they could be included on the smallest of pads.

Indium metal bumps can be deposited on the pads by means of electro-plating or vacuum sputtering or evaporation after defining the geometry of the bumps using photolithography techniques. The typical size of the indium bumps are less than 25 μm in length or width and less than 15 μm high. Indium bump bonding was originally developed for hybridization assembly of IR detectors with very small pixels on fine pitches and has been adapted with limited success for assembly of other types of detectors with larger pixels on larger pitches. The process of assembly typically requires indium metal bumps to be deposited on the pads of both surfaces that are to be interconnected. The indium bumps are then accurately aligned and “cold-welded” together using a high compression force between the mating surfaces with or without low heat (≦100° C.) to aid wetting between the indium bumps, since indium metal bumps quickly begin to oxidize when exposed to air. Since both mating surfaces require deposition of the indium bumps, the processing costs are relatively high, unless multiple devices can be processed together on a single wafer. In addition, unless the mating surfaces are very coplanar, the resulting pixel connections may later separate and fail due to thermal expansion mismatch of the mated materials or from latent shear or tensile stresses as the bowed surface(s) rebound after the compression force is removed. Another disadvantage for indium bump bonding is the extremely narrow gap resulting between the mating surfaces after the indium bump bonds are compressed and cold-welded together. The narrow gap between mating surfaces can induce parasitic capacitance that may degrade the performance of sensitive ASIC readout devices. This problem was documented in a technical paper co-authored by this applicant [“Assembly Technique for a Fine-Pitch, Low-Noise Interface; Joining a CdZnTe Pixel-Array Detector and Custom VLSI Chip with Au Stud Bumps and Conductive Epoxy” IEEE Nucl. Sci. Symp. Conf. Rec. 5:3513 (2003)] and for background purposes that publication is included herein by reference in its entirety.

FIG. 2B is very similar to FIG. 2A with exception that the indium bumps 16 are replaced with solder alloy balls or bumps 18 residing on only the detector's anode pads 6 and guard ring contact ribbon 10. Solder balls or bumps may be deposited on either the detector pads or substrate pads (not shown) by means of solder plating (typically at the wafer level), drop placement, solder jetting, and various other methods. In addition, wet solder paste may be screen or stencil printed or dip transferred onto the pads and either reflowed into rigid balls or bumps before assembly onto the substrate 12, or assembled in the wet state onto the substrate and reflowed into a solid state as a single process step. Solder bump placement and subsequent bump bonding by SMT techniques are well known and practiced within the electronic industry.

In recent years there has been an international requirement (RoHS) to eliminate the use of lead (Pb) as an alloy metal within solder compositions for environmental reasons. In order to retain narrow eutectic melting points for non-leaded solder compositions, the industry has moved to substituting silver (Ag), copper (Cu), bismuth (Bi), zinc (Zn) and/or indium (In) in various ratios with tin (Sn). Unfortunately, the resulting melting points of these non-leaded alloys are typically higher than the former SnPb alloy. An exception would be Snln alloys which melt at temperatures as low as 118° C. However, many detector crystals cannot be exposed to temperatures above 100° C. before they begin to anneal and change characteristics. Therefore, solder bump bonding is used typically for only silicon based detectors that are not temperature sensitive. Another intrinsic problem with either lead or indium solder bumps is the presence of radioactive trace elements that can produce alpha particles that may affect the performance of highly sensitive ASIC readout chips. Yet another problem with solder based bump bonding is the tendency of the solder alloys to amalgamate with thin film gold pixel pads used on many X-ray and Gamma-ray detectors, causing the pads to vanish or the solder to become brittle. This problem is aggravated by the large thermal mass many detectors exhibit, which can retain temperatures above the eutectic melting point of the solder alloy longer than desired. For these and other reasons, solder alloy bump bonding is not a preferred method for assembling temperature sensitive detectors to substrates or ASIC readout devices.

FIG. 2C illustrates another prior art hybridization technique for assembly of pixel detectors. In this cross section view an Anisotropic Conductive Adhesive (ACA) film or paste 20 is placed between the mating surfaces of the detector and substrate or ASIC readout IC chip. Anisotropic Conductive Adhesive films or pastes consist of either a thermoplastic or thermoset adhesive or epoxy that can be rapidly (“snap”) cured and cooled to affect an adhesive bond between the surfaces. “Hot-melt” adhesives would be a type of thermoplastic adhesive that can be easily softened and separated after bonding by re-heating the adhesive material. Epoxies, on the other hand, are thermoset adhesives and do not readily soften when re-exposed to high temperatures. Inside the thermoplastic/thermoset adhesive/epoxy are randomly distributed, electrically conductive, particles that become trapped between the opposing contact pads when a compression force is applied between the surfaces as the adhesive/epoxy cools below the glass transition temperature and provide a path for electrical conduction between the adjacent detector and substrate pads. The conducting particles are mixed as a fairly low loading percentage (3-12%) of the adhesive/epoxy matrix in order to prevent electrical conductivity by particle-to-particle contact in the lateral plane of the adhesive bond. Hence this type of adhesive or epoxy is termed as an anisotropic conductive adhesive, since it conducts in only one direction; vertically and not laterally between contact pads.

Various types of metal particles can be used to provide electrical conductivity between the pads of the detector and substrate or ASIC chip. Typically gold, copper or nickel spheres, that are approximately 5-20 μm in diameter, are used. Some adhesives include solder alloy spheres that may partially melt and affect an electrically conductive ACA connection. Other types include metal-coated polymer spheres, which provide some degree of compliancy between the electrically connected pads during thermal cycling. Yet another ACA adhesive has used microscopic iron rods with plated gold or copper coatings that can be aligned in a vertical axis between the pads by means of an applied magnetic field before allowing the thermoset epoxy to cure or the thermoplastic adhesive to cool.

Each of these ACA adhesives or epoxies has unique advantages and disadvantages. Although ACA adhesive bump bonding has been employed quite successfully for many years for attaching flexible cables to glass LCD displays, their use for assembling detectors requires some modification of the surfaces for reliable pixel interconnections. In particular many detectors have very brittle or soft bulk material properties, which do not readily retain the bonded surfaces in sufficient compression during temperature cycling to yield reliable pixel connections. If the particles are too hard, they may pierce through the thin film metal pads of CdZnTe, CdTe or TIBr detectors, for instance. If the thermoplastic adhesive has a fairly low softening temperature, adequate compression force between the surfaces may be lost if the assembly is exposed to too high a temperature. Virtually all ACA adhesives require the pads, which are to be electrically joined, to be raised several microns (typically 5 μm minimum) above the surface of the detector and/or the substrate/ASIC chip. This is to ensure that the conducting particles are not inadvertently compressed between the detector and other traces or test pads on the substrate or ASIC chip causing a shorted connection. Since the pads of many detectors are vacuum deposited thin film metal, this is not practical. Finally, the resulting thin bond line thickness, typical with ACA adhesive/epoxy bump bonding, suffers from the same parasitic capacitance problem as with indium bump bonding.

FIG. 2D illustrates another prior art hybridization technique for assembly of pixel detectors. In this cross section view Isotropic Conductive Adhesive (ICA) bumps 22 are needle dispensed, screen printed, stencil printed, ink-jet printed or dip transferred onto either the detector pads, as shown, and/or the substrate or ASIC readout chip pads (not shown). Isotropic Conductive Adhesive inks or epoxies consist of a solvent or polymer resin with a high percentage of loading (>60%) of conductive metal flakes, typically silver in a bimodal distribution of sizes. The individual metal flakes agglomerate as the solvent evaporates or the polymer resins cure and shrink to bring the flakes into electrical contact with one another. Some electrical conductivity may be contributed (or achieved even without a metal flake filler) by a polymer resin that is intrinsically electrically conductive or by ballistic tunneling through the thin insulating resin that coats the metal flakes, when a sufficient voltage is applied across the contact pads joined by the ICA adhesive. In recent years, carbon and silver nanoparticle technology has been developed to improve the electrical conductive properties of ICA adhesives and their use for electronic assembly is expected to substantially increase.

Unlike Anisotropic Conductive Adhesives (ACAs), Isotropic Conductive Adhesives (ICAs) are electrically conductive in all directions. Typically the ICA bumps are deposited onto the pads of the upper component being assembled, the detector in this case, and flip chip assembled to the pads of the substrate or ASIC readout chip, while the ink or epoxy is still wet. After drying the solvent or curing the resin, the bumps provide both mechanical and electrical connections between the adjacent pads. Depending on the total number (bonded area) and mechanical shear strength of the ICA bump bonds, it may be necessary to dispense and cure a separate insulating underfill epoxy between the joined surfaces of the assembled components to increase the mechanical strength of the bond line. Since all polymer resins tend to be somewhat hygroscopic, the underfill epoxy also helps prevent or postpone fluctuations or changes in the bulk resistance of the ICA bonds.

As described earlier for ACAs, ICAs also exhibit both unique advantages and disadvantages. ICAs, for instance, can be readily applied between contact pads that are not raised above the joining surfaces and will provide excellent electrical conductivity without having to maintain a compression force between the surfaces. However, the wet bumps are easily compressed and may spread between two flat surfaces sufficiently to cause electrical shorts between closely spaced adjacent pads. Until fully dried or cured, the ICA bumps are also easily misaligned when accidentally mishandled. And again, the resulting thin bond line may cause a problem with parasitic capacitance between the joined surfaces.

To compensate for the disadvantages noted above, an improved ICA bump bonding technique was developed several years ago and is illustrated in FIG. 2E. In this example of prior art, small gold or copper ball/stud bumps 24 are pre-bonded to the pads of the substrate or ASIC readout IC. Typically the gold or copper ball/stud bumps are thermosonic bonded to the substrate or ASIC pads using a wire bonder with a specific wire bonding parameter or program created for shaping the ball/stud bumps to the required dimensions. Typical dimensions for gold stud bumps are 55-60 μm diameter and 35-45 μm high. Copper ball/stud bumping is also feasible, but is presently more suited for bumps placed on a substrate rather than an ASIC, due to a tendency of rigid copper bumps to crack the silicon under the pads. One advantage for using gold stud bumps on the pixel pads of the ASIC readout IC is that the gold ball/stud bumps may be attached directly to the aluminum metallized pixel pads. Since aluminum does not form a reliable electrical contact with ICA adhesives or epoxies, because of the aluminum oxidation that forms on the surface of the pads, adding gold ball/stud bumps provides a noble metal contact surface that is compatible with ICA type adhesives and epoxies.

During assembly, the wet ICA bump height and diameter can be controlled to contact only the gold stud bumps 24 and not come into contact with the surface of the ASIC chip. As the detector epoxy bumps are aligned and brought into contact with the raised gold stud bumps, the epoxy envelopes the tips of the stud bumps and flows partially around the base of the stud bumps. The tips of the gold stud bumps act as a limiting spacer or stand-off that prevent the epoxy bumps from being compressed and spreading laterally to cause electrical shorting between the adjacent pixel pads that may be closely spaced. Since the resulting bond line thickness cannot be less than the height of the array of gold stud bumps, the parasitic capacitance between the joined surfaces is improved. If necessary, an underfill insulating epoxy (not shown) may be dispensed between the anode surface of the detector and the pixel readout surface of the substrate or ASIC device.

FIG. 2F illustrates yet another prior art hybridization technique for assembly of pixel detectors. In this cross section view an electrically conductive elastomeric film 26 is sandwiched and compressed between the detector's anode pads 6 and the pixel readout pads 14 of the substrate or ASIC. The elastomeric film may be composed of silicon or rubber like material with closely spaced rows and columns of electrically conductive pillars composed of conductive particles such as silver flake, carbon black, carbon nanotubes and other similar electrically conductive particles. This type of connector performs similarly to ACA adhesives or epoxies, when held in a state of compression between the surfaces. This type of connector is typically used as a temporary means for establishing electrical connections between the pixel pads of the detector and the pixel readout pads of the substrate or ASIC readout device for testing purposes. One advantage of this assembly method is that the detector is readily dismantled from the substrate or ASIC readout chip and this enables many detectors to be mated and tested on the same substrate or ASIC readout device. In order to apply a sufficient compression force to complete electrically conductive paths through each of the individual pillars disposed between the pads, pressure is typically applied to the top Cathode surface of the detector. This adds an undesirable bulk, weight, height, and/or obstruction to the impingement of the high energy photons on the Cathode surface of the detector and is why this type of connection is mainly intended for temporary purposes only.

Compression Decals

When fully cured, thermoset epoxy-resin Isotropic Conductive Adhesives (ICA) bumps described above are sufficiently strong that the application of an underfill epoxy is often unnecessary. However, if it becomes desirable to later disassemble the ICA bonded surfaces, the epoxy bumps are extremely difficult to dissolve and remove from fragile sensors or detectors without causing damage to the components. Therefore, an alternative means for establishing compression type interconnections, which exhibit high electrical conductivity, yet may be easily removed and replaced when disassembly is required, are described below as “compression decals.”

### EXAMPLE

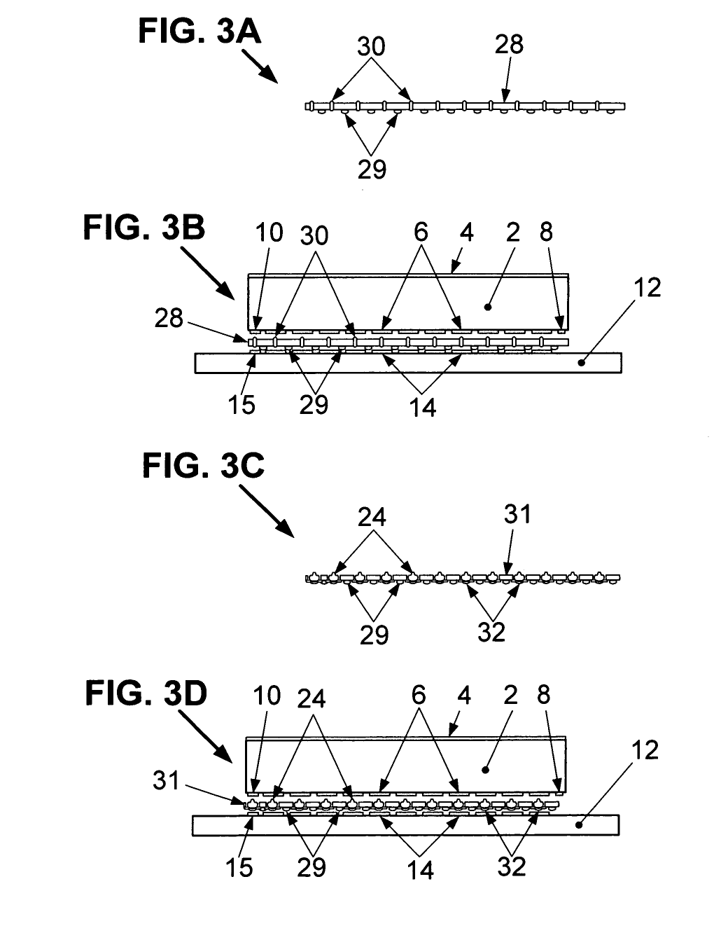

As shown in FIG. 3A, an electrically conductive, ICA bumped, compression decal 28 according to the present invention is disclosed in a cross section view. This decal consists of a thin flexible film such as polyimide Kapton™, Mylar™, PEN, PET, ABS or other similar electrically insulating flexible dielectric film, which is preferably about the same size and shape as the surfaces being electrically joined and includes small via-holes through the thickness of the film. The via-holes may be formed in the film using a variety of methods including drilling, punching, laser-cutting, water-jet or abrasive-jet cutting, die piercing or etching, as are well known in the art. The via-holes are arrayed in a grid pattern through the film to correspond with the X and Y-axis pitch of a detector's anode pads and pad dimensions and/or substrate, interposer, or ASIC readout pixel pads. The via-holes are preferably no larger than about 50% of the dimensions of the anode/pixel pads. Additional holes (not shown), near the corners of the decal, may be optionally included for alignment or registration purposes, to engage with alignment pins located on the substrate or interposer. Alternatively, a semi-tacky or pressure-sensitive, temporary contact adhesive layer or array of contact adhesive dots 29 may be placed on one or both surfaces of the decal to aid in the placement and fixed positioning of the decal with respect to the pads on the substrate, interposer or ASIC readout device and/or detector. These adhesive dots extend sufficiently in height above the electrically conductive compression bumps that they contact the surface of the interposer and/or detector to adhere and hold the decal in proper alignment with the pads to be interconnected. The type and amount of adhesive is designed to allow the decal to be readily removed and replaced during reassembly, if required.

Electrical connections between the top and bottom surfaces of the decal 28 are enabled by ICA filled via contacts 30 that are preferably stencil printed on both sides of the film directly over the patterned array of via-holes. To function properly, the electrically conductive bumps of fully cured ICA ink or epoxy should extend or protrude above both sides of the film, preferably about 10% and more preferably about 20% of the thickness of the dielectric film, as illustrated in FIGS. 3A and 3C, and be able to be compressed without cracking (semi-elastic).

The cross section view of FIG. 3B illustrates the decal 28 of FIG. 3A disposed between the surfaces of a detector 2 and substrate or ASIC readout device 12. In a manner similar to the elastomeric connector film 26 previously described above, electrical interconnections between each individual pixel pad on the detector and readout pad on the substrate or ASIC device is achieved by a compression force applied to the top Cathode surface of the detector. The main advantages for this compression decal is a lower manufacturing cost, better charge carrying capability using fully-cured ICA bumps and raised contact surfaces of the bumps on both sides of the film to enable better electrical contact with the pads using less compression force. In addition, the decal can be disposed of or recycled after each use, as the bumps provide a fairly compliant contact between the opposing pads.

### EXAMPLE

A method for fabricating the ICA bumped compression decal 28 disclosed in FIG. 3A would consist of the following steps:
1. Forming a patterned array of via-holes through a flexible film.
2. Depositing Isotropic Conductive Adhesive (ICA) bumps on a first side, directly over the via-holes.
3. Curing the ICA bumps on the first side. (It will be understood that as used herein, the “curing” step may involve any process such as cross-linking, solvent removal, drying, etc., as are familiar in the art.)
4. Depositing Isotropic Conductive Adhesive (ICA) bumps on a second side, directly over the via-holes.
5. Drying or curing the ICA bumps on the second side.
6. Adding adhesive dots to the first side and/or second side.

### EXAMPLE

Another version of a compression decal 31 is disclosed in the cross section view of FIG. 3C. This decal consists of a thin flexible dielectric film, as previously described, with a thin copper film etched into an array of pads on the bottom surface of the flexible film. Directly above the etched pads are openings within the flexible film that expose a center portion of each thin copper pad from the opposite surface of the copper film. Gold or copper ball/stud bumps 24, as previously described, are thermosonic bonded through the openings within the flexible film and adhere to the pads at the bottom of the openings. In this example the copper film is very thin, typically within the range of 9-18 μm, and forms a pad with a dimpled bottom 32 as a result of deformation during the thermosonic bonding process. The diameter and height of the ball/stud bumps and thickness of the surrounding flexible film are preferably optimized to enable the tips of the ball/stud bumps 24 to project approximately 20-30 μm above the upper surface of the flexible dielectric film and the bottom dimple within the pads to also extend approximately 10-20 μm above the bottom surface of the film. As previously disclosed, adhesive dots 29 can be added to one or both surfaces of the decal to aid in the placement and fixed positioning of the decal with respect to the pads on the substrate, interposer or ASIC readout device and/or detector.

The cross section view of FIG. 3D illustrates the decal 31 of FIG. 3C disposed between the surfaces of a detector and substrate or ASIC readout IC. Electrical interconnections between each individual pixel pad on the detector and readout pad on the substrate or ASIC device are achieved when a compression force is applied to the top Cathode surface of the detector. The main advantages for this compression decal are finer pitched contacts, and even better charge carrying capability of the gold or copper ball/stud bumps and raised contact surfaces created by bumps on both sides of the film. As before, this decal can also be disposed of or recycled after each use, as the bumps provide a fairly compliant contact between the opposing pads.

### EXAMPLE

A method for fabricating the ball/stud bumped compression decal 31 disclosed in FIG. 3C would consist of the following steps:
1. Forming a patterned array of pads on the surface of a single-sided, copper-clad, flexible film.
2. Forming open windows through the flexible film centered over the pads.
3. Thermosonic bonding gold or copper ball/stud bumps to the pads exposed through the open windows in the flexible film, causing dimpled bumps on the exposed copper pads on the bottom or side two surface of the flexible circuit and protruding tips of the stud bumps on the top or side one surface of the flexible circuit.

### EXAMPLE

An alternative method for fabricating the ball/stud bumped compression decal 31 disclosed in FIG. 3C would consist of the following steps:
1. Forming a patterned array of open windows through the surface of a flexible film.
2. Laminating a thin copper sheet to one surface of the flexible film.
3. Forming a patterned array of pads, centered over the array of open windows within the flexible film.
4. Thermosonic bonding gold or copper ball/stud bumps to the pads exposed through the open windows in the flexible film, causing dimpled bumps on the exposed copper pads on the bottom or side two surface of the flexible circuit and protruding tips of the stud bumps on the top or side one surface of the flexible circuit.

One preferred version for the compression decal 31 disclosed in FIG. 3C could use single-sided, adhesiveless, copper-clad, polyimide films similar to that available as the DuPont™ Pyralux AP brand of flexible circuits. The etched pads could be finished with gold plated coatings on both surfaces of the exposed copper pads to prevent the formation of oxides that could inhibit reliable thermosonic bonding of the ball/stud bumps or electrical contact during compression mating against the pads on the detector, substrate or ASIC readout chips. Also, the total thickness of the thermosonic bonded ball/stud bumps and gold-plated copper pads should be greater than the thickness of the flexible film after compression between the pads of the detector and substrate/ASIC surfaces.

It should be noted that the array of thin copper pads on the bottom of the flexible film may also be connected individually or in rows and/or columns with narrow circuit traces that radiate to additional pads located at the edges of the flexible circuit for some applications, for example, to build a so-called Stripe Detector. In a Stripe Detector the cathode comprises a series of independently-biased parallel strips and the anode contacts are arranged in parallel rows perpendicular to the cathode strips so that the area of overlap between one cathode strip and one row of anode contacts defines a particular pixel.

UV-Cured Compression ACA

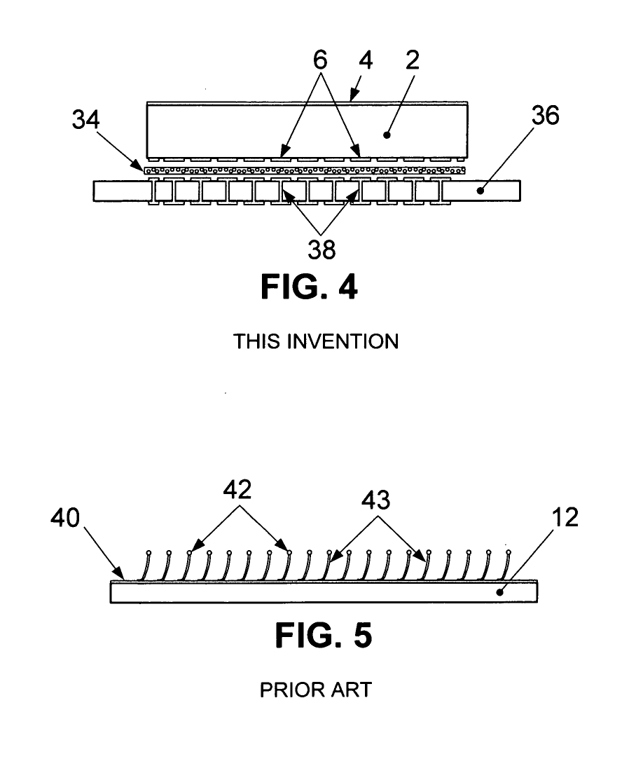

Turning now to FIG. 4, an electrically conductive, UV-cured, ACA paste 34 is disclosed that consists of a UV-cured polymer adhesive paste that contains randomly distributed conducting particles, as previously described. UV-cured adhesives or epoxies provide significant advantages for rapid curing using little or no heat. However, in order to provide sufficient UV light for photo-initiation of the curing catalyst, the surfaces being joined must be transparent to the correct wavelength of the UV-curing lamp.

### EXAMPLE

One possible solution is to substitute an optically clear interposer or substrate 36 for mounting the detector. FIG. 4 illustrates a detector 2 being assembled to an optically clear interposer 36 that includes an upper and lower array of pixel readout pads that are directly opposite one another and that are electrically connected through conductive via interconnections 38. Interposers are often used for permanently mounting fragile detectors that require frequent handling for testing purposes and the use of a UV-cured, ACA paste 34 would quickly speed their assembly, since little or no heat would be required to cure the adhesive. In addition, the UV-cured adhesive would enable detectors and substrates with dissimilar thermal expansion characteristics to be assembled at room temperature with little or no shear stress present after curing.

### EXAMPLE

In yet another example of the invention, illustrated in FIG. 4, the UV-cured ACA paste 34 contains not only electrically conductive particles, but also a mixture of powdered phosphor(s) that down-convert high energy X-ray or Gamma-ray photons to UV-light which provides sufficient photo-initiation to cause the paste to cure. In this case, no external UV-curing lamp light source is required, nor is an optically transparent interposer or substrate required. The UV-curing light is internally generated within the matrix of the paste itself, when exposed to high energy photons directed in a steady or pulsed beam from an X-ray or Gamma-ray generating source. The resulting down-converted UV-light causes the epoxy to cure, holding the surfaces in compression and enabling the conductive particles or spheres to make electrical continuity between the aligned contact pads of the opposing surfaces. This approach is taught in U.S. Pat. No. 9,023,249, the entire disclosure of which is incorporated herein by reference. In a preferred example of this invention, the UV-phosphor is applied as a coating to the surface of the conductive particles and acts as an electrically insulating surface surrounding the conducting particles, which breaks apart to expose the electrically conductive surfaces under the insulating coating, when the particles are compressed between two raised pads. This enables the particle loading within the UV paste to be less sensitive to inadvertent lateral electrical conduction between adjacent pads that are spaced close together.

Vertical Wire Bonding

FIG. 5 illustrates a prior art, cross section view of an inert substrate (i.e., the substrate contains no electrical circuitry and its only function is to hold the FAB samples in position for optical inspection). A linear array of leaning vertical wire bonds, which terminate with Free Air Balls (FAB) are arranged thereon. A Free Air Ball 42 is a spherical ball of gold formed at the tip of a gold wire after it is threaded through a ceramic capillary and is a critical part of the gold-wire ball bonding process used for interconnecting electronic silicon integrated circuits. The gold ball forms a first connection to a circuit pad by means of ultrasonic scrubbing of the ball against a circuit pad pre-heated to an elevated temperature (typically 150° C.). Hence, the gold-ball bonding process is considered to be a “thermosonic” wire bonding process. This process is well known within the art of electronic assembly and is very pervasive in its usage.

The technique of vertical wire bonding with FABs shown schematically in FIG. 5 was developed to enable automated microscopic examination of the gold balls to determine the uniformity of the Electronic Flame Off (EFO) process used to melt and form the gold balls. Photos of bonded arrays of FABs on various substrates and IC chips are available from Kulicke and Soffa Industries, Inc, (K&S), a manufacturer of gold and copper wire bonding equipment.

FIG. 5, then, is an example of a linear array of leaning vertical wire bonds with FABs 43, that are thermosonic bonded to the gold coated surface 40 of a substrate 12 and which terminate in Free Air Balls (FABs) 42 formed from gold wire. FIG. 5 is intended to replicate the shape and angle of the FABs in these test arrays, as depicted in photos available from K&S.

Applicant realized that the K&S array of freestanding FABs, vertically bonded to a substrate, might be modified to form a contact array for the assembly of various imaging sensors or detectors. The FABs at the tips of the vertical bonds provide a rounded contact surface that is less likely to scratch through the surface of fragile anode pads on many detectors, which are typically extremely thin and easily punctured. Though clearly not intended for this purpose, Applicant further realized that the FABs formed at the tips of the vertical wires might also provide an excellent mechanical anchor when imbedded within larger encompassing bumps consisting of dispensed or stencil printed electrically conductive ink, epoxy, or solder paste.

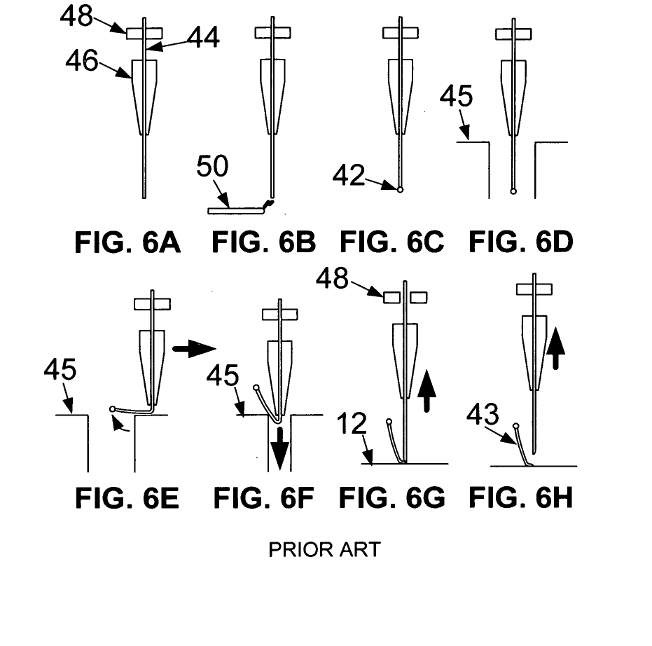

A wire bonding program for producing an array of FABs on a gold coated substrate, as illustrated in FIG. 5, is available from K&S for use on their gold wire bonding equipment. From discussions with K&S, the procedure used to form and bond the FABs consists of the following steps as depicted in the cross section drawings of FIGS. 6A-6G.
1. At the end of the previous bonding cycle, a straight section of gold wire 44, which is threaded through a ceramic wire bonding capillary 46, is held in place by a clamp 48 in its closed position. The gold wire protrudes approximately 2 mm beyond the tip of the capillary as the bonding head, which holds the capillary, moves upward to a rest position (FIG. 6A).
2. An electric voltage with low current is applied to the tip of the Electronic Flame Off (EFO) wand 50, causing an arc to be transferred across an air gap to the tip of the protruding gold wire (FIG. 6B).
3. The transferred voltage/current arc melts the tip of the gold wire, forming a Free Air Ball (FAB) 42 at the end of the gold wire (FIG. 6C).
4. The bonding head moves the capillary tip over a hole formed in the surface of a wire forming tool 45 and lowers the FAB near the bottom of the hole (FIG. 6D).
5. The capillary remains above the surface of the wire forming tool 45 and then sweeps in the direction of the arrow, causing the wire to touch the edge of the hole and to bend upward and into a right angle as the capillary tip continues to travel a short distance across the tool's surface (FIG. 6E).
6. The bonding head continues to move the capillary across the surface of the wire forming tool until it reaches the center of another smaller diameter hole. The capillary then drops slightly below the top edge of the second hole, causing the wire to contact the edge of the hole and bend into almost a vertical angle (FIG. 6F). The upward travel of the wire and FAB as it is formed into a vertical wire is limited by the shape of the capillary.
7. The capillary then moves over to the position for placement of the vertical wire bond and lowers to perform a wedge-bond onto the gold coated surface of the substrate. At the completion of the wedge-bond, the wire clamp 48 opens and allows the gold wire to pay out as the capillary is raised from the surface of the substrate 12 (FIG. 6G).
8. When the capillary reaches the correct distance above the substrate, the clamp closes again and causes the gold wire to break free from the wedge-bond as the capillary continues to rise to the start of the next FAB forming cycle. The leaning vertical wire bond with FAB 43 remains attached to the substrate. (FIG. 6H).

Applicant realized that if an array of vertical wire bonds with FABs, as described above, are formed with uniform height and are accurately positioned in both the X and Y-axis to match the array of anode pads of a sensor or detector, this type of vertical wire bond would be very useful for the assembly of detectors for the following reasons:
1. Elevating the detector or sensor from the surface of the substrate or ASIC readout device significantly reduces the problem with parasitic capacitance due to close coupling of the metal fields and traces on the interior surfaces.
2. The vertical wire bonds substantially decouple the thermal expansion differences between the detector and the substrate or ASIC readout chip. This would be especially desirable for the assembly of Thallium-Bromide (TIBr) detectors on silicon ASIC readout chips, since TIBr detectors have a very large coefficient of thermal expansion (CTE) compared to silicon. This eliminates the frequent necessity for an underfill epoxy between the joined surfaces.
3. The vertical wire bonds enable cool air or a cooling liquid to circulate between the detector and its mating substrate and the long, thin, gold wires act as a thermal impedance between the two devices. This is important when the detectors must be operated at a low temperature.
4. The FABs formed at the tips of the vertical wires provide an excellent mechanical anchor when surrounded and enclosed within larger connecting bumps consisting of electrically conductive ink, epoxy or solder.
5. The exposed wires may be readily cut or sheared to separate expensive detectors for rework and reuse on other substrates.
6. The long, thin, yet flexible vertical wire bonds enable the edges of adjacent detectors to be manipulated together to maintain uniform pixel pitches across tiled detectors and provide a degree of shock absorption.
7. The length of the vertical wire bonds can be adjusted to compensate for detectors of different thickness or to enable tiled detectors to overlap at their edges by assembling the detectors on arrays of vertical wire bonds of alternating heights.

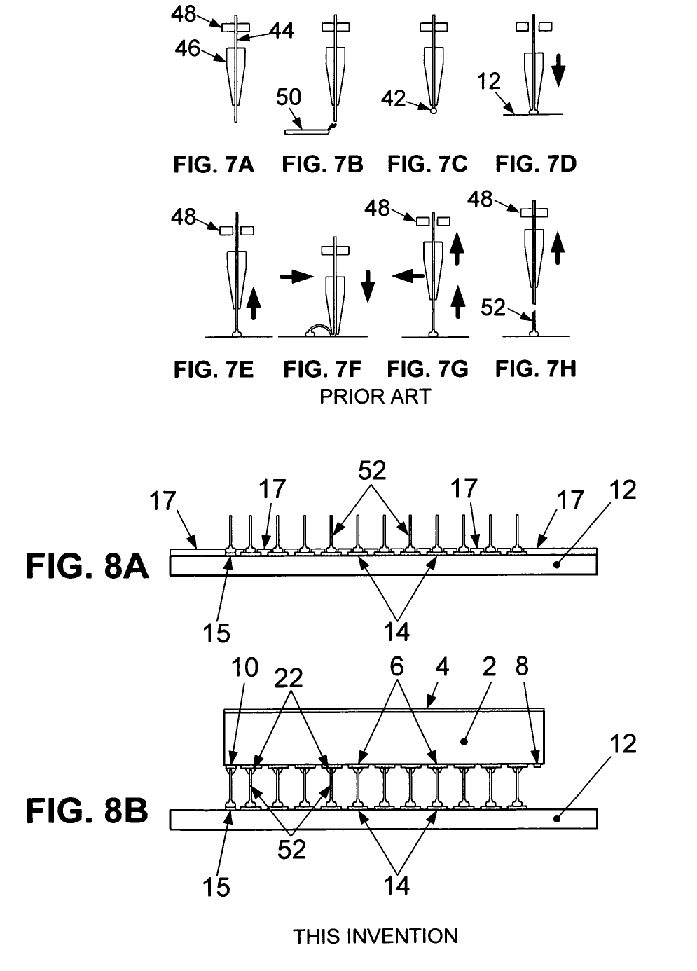

Unfortunately, the prior art process used to create the leaning vertical wire bonds with FABs 43 does not currently provide sufficient accuracy for assembling imaging sensors or detectors with large arrays of anode pads, even those with fairly large pitches. The process steps shown in FIGS. 6A-6H form a vertical wire bond that is leaning with respect to the point of attachment on the substrate due to the obstruction of the tapered capillary. Kulicke and Soffa, however, recently developed and introduced a “modified” straight vertical wire forming process that provides better positioning accuracy. The steps used to form a straight vertical wire bond without a FAB 52 are depicted in the cross section views and steps of FIGS. 7A-7H:
1. At the end of the previous bonding cycle, a straight section of gold wire 44, which is threaded through a ceramic wire bonding capillary 46, is held in place by a clamp 48 in its closed position. The gold wire protrudes approximately 0.2 mm beyond the tip of the capillary as the bonding head, which holds the capillary, moves upward to a rest position (FIG. 7A).
2. An electric voltage and low current is applied to the tip of the Electronic Flame Off (EFO) wand 50, causing an arc to be transferred across the air gap to the tip of the protruding gold wire (FIG. 7B).
3. The transferred voltage/current arc melts the tip of the gold wire, forming a Free Air Ball (FAB) 42 at the end of the gold wire (FIG. 7C).
4. The wire clamp opens and the bonding head moves the capillary tip into position over substrate 12 before dropping down against the substrate pad with sufficient force, ultrasonic scrubbing energy, and heat from the substrate to cause the FAB to deform and make a ball bond to the surface of the substrate (FIG. 7D).
5. With the wire clamp 48 remaining open, the bonding head raises the capillary as gold wire is paid out until the tip reaches the correct height for forming the vertical wire bond (FIG. 7E).
6. The wire clamp then closes and the bonding head moves laterally and then down again to bring the wire to contact the surface of the substrate 12 and form a loop of gold wire still connected to the ball bond. These steps are identical to forming a standard gold-ball wire bond, except that no ultrasonic energy is generated to make a wedge-bond. Only sufficient force is applied to “crimp” the gold wire, flattening its diameter and weakening the wire without causing it to adhere to the surface of the substrate (FIG. 7F).
7. The bonding head then reverses its previous direction of travel, moving up and laterally to bring the capillary directly over the ball bond again. The wire clamp 48 opens momentarily as the bonding head moves a short distance up again while more gold wire is paid out to form the next FAB (FIG. 7G).
8. Wire clamp 48 closes again and the bonding head raises the capillary again causing the wire to straighten and break at the point of the crimp. The straight vertical wire bond without a FAB 52 remains attached to the substrate (FIG. 7H).

One major limitation of this straight vertical wire forming process is related to FIG. 7F above. The wire must be looped over and contact the surface of the substrate or ASIC readout device 12, in order to “crimp” and weaken the wire prior to pulling it taut and breaking it. However, the surfaces on some substrates or ASIC chips may contain structures that are sensitive to the forces imparted by the capillary or that obstruct the location where the “crimping” process needs to be performed. In fact, large arrays of vertical wire bonds fill virtually the entire surface of the substrate of ASIC chip as they are formed, and as the far edge of the substrate or ASIC chip is approached, there is no available room left to perform this step directly on the surface of the device being bonded. At this point the crimping step must be performed by looping and contacting the wire against a separate flat surface located adjacent to the surface receiving the vertical wire bonds.

### EXAMPLE

A solution for preventing damage to sensitive lines and traces or other active structures on the surface of substrates or ASIC chips 12 is shown in FIG. 8A. Substrate 12 includes a linear array of straight vertical wire bonds without FABs 52 that are not crimped directly against the surface of substrate 12, but instead against the surface of a hardened photo resist layer 17. The photo resist layer would be applied in liquid form to the surface of substrate 12 by spin coating, roller coating, or spray coating, or as a film by lamination. After baking the liquid photo resist dry, layer 17 would be exposed to UV light through a photo mask to selectively alter the solubility of the photo resist during immersion in a developing solution. After the photo resist is developed, it would then be baked at high temperature to harden the surface sufficient to enable wires 44 to be “crimped” by the capillary during formation of the “modified” straight vertical wire bonds without damaging the sensitive structure on the surface of substrate 12. If the photo resist does not exhibit sufficient rigidity to properly crimp the wire, then a thin metal layer (not shown) may be substituted for layer 17 or added over layer 17 and photo defined to aid in the rigidity of the crimping surface. After completion of the “modified” straight vertical wire bonding process, the photo resist layer 17 and/or metal layer may be removed by techniques well known in the art of IC fabrication or left in place.

### EXAMPLE

In accordance with the description above, a method for forming an area array of straight vertical wire bonds without FABs to the pixel readout pads of a substrate, interposer or an ASIC readout chip consists of the steps of:
1. Applying a photoresist layer to the surface of a substrate, interposer or ASIC readout die or wafer.
2. Baking the photoresist dry.
3. Selectively exposing the photoresist to UV light through a patterned photomask to selectively alter the solubility of the photo resist over each pixel readout pad during immersion in a developing solution.
4. Developing the photoresist by immersion in a developing solution to expose the pixel readout pads through the surrounding and remaining photoresist.
5. Rinsing and drying the substrate, interposer or ASIC readout IC die or wafer.
6. Baking the photoresist at a high temperature to harden the photoresist.
7. Forming straight vertical wire bonds without Free Air Balls by forming in sequence, a standard gold or copper ball bond to the pixel pad, looping the wire and crimping the wire, at a certain distance from the ball bond, against the surface of the hardened photoresist, pulling the wire directly above the ball bond until the wire breaks at the crimped location on the wire, and repeating these steps for the remaining pixel readout pads that are set back from the edge of the device by a distance greater than the length of the vertical wire bonds.
8. Forming straight vertical wire bonds without Free Air Balls on the remaining pixel pads that are not set back from the edge of the device by a distance greater than the length of the vertical wire bonds, by looping and crimping the wire onto an adjacent rigid surface at the same height as the device.
9. Removing the hardened photoresist in a preferably heated developing solution.
10. Rinsing and drying the substrate, interposer or ASIC readout IC die or wafer.

### EXAMPLE

FIG. 8B discloses an example of the detector 2 from FIG. 2E that has been assembled to an array of straight vertical wire bonds 52 without FABs placed on the pixel readout pads 14 of a substrate or ASIC readout device 12, as described above. With probable exception of item 4 from the list of advantages for vertical wire bonds with FABs, this embodiment retains all of the other advantages listed, and further enables the vertical wire bonds to be more accurately aligned with the anode pads of the detector.

Though quite thin and easily damaged, if not carefully handled, the thin wires will function as a “bed-of-nails” to support the weight of the heavier detectors during flip chip placement. The tips of the wires are also expected to fully penetrate the ICA bumps 22, as illustrated in FIG. 8B, during curing with little or no additional pressure required than the weight of the detector itself. However, if too much pressure is applied during flip chip assembly, a problem may arise from this type of vertical wire bond if the wire is formed from copper. Because these wires are crimped before breaking, the tips will tend to have sharp points and the copper tips may pierce through the extremely thin metal pads and into the bulk material of many types of sensors and detectors. This will cause problems with the performance of the sensors/detectors and possible failure of the imaging pixels. Therefore, gold is the preferred wire used for these “modified” straight vertical wire bonds, since it is more malleable and less likely to damage the fragile pads. Another problem is related to the adhesion of the sharp tips embedded into the ICA adhesive bumps or low-temperature solder bumps. Since the crimped and pointed tips offer less surface area for bonding than the FAB tipped wires, the connections may be at risk if too much strain or shear is exerted on the detector after assembly.

Forming Vertical Wire Bonds with Fewer Process Steps

### EXAMPLE

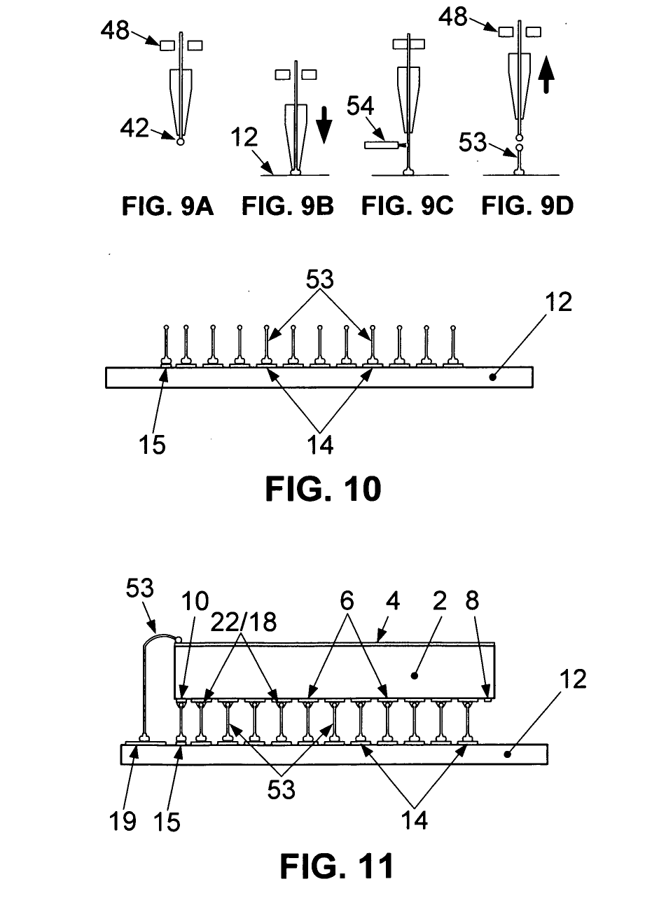

Considering the number of steps involved to form the “modified” straight vertical wire bonds 52, it would be highly desirable to reduce this process to fewer steps and add a FAB on the tips of the wires. Therefore, an inventive wire bonding process, requiring only four steps for forming a preferred straight vertical wire bond with FAB 53, is disclosed in the following illustrated steps and views of FIGS. 9A-9D.
1. The bonding cycle begins with the FAB pre-formed at the end of the gold or copper wire protruding from the capillary with the wire clamp 48 open (FIG. 9A).
2. The wire clamp remains open as the bonding head moves the capillary tip into position over substrate 12 before dropping down against the substrate pad with sufficient force, ultrasonic scrubbing energy, and heat from the substrate to enable the FAB to deform and make a ball bond to the surface of the substrate (FIG. 9B).
3. With the wire clamp 48 remaining open, the bonding head raises the capillary as the wire is paid out until the tip reaches the correct height for forming the vertical wire bond. At this point, the clamp closes and a laser beam, plasma jet, or hydrogen flame intersects and cuts the wire while simultaneously melting both ends of the cut wire to form FABs (FIG. 9C).
4. The clamp 48 then opens and the bonding head raises the capillary and proceeds to the next bonding site, leaving a straight vertical wire with FAB 53 remaining attached to the substrate (FIG. 9D).

### EXAMPLE

Since the FAB formed by the laser or hydrogen flame in FIG. 9C can lead to a brittle area within the “neckdown” portion immediately above the FAB, the ball below the capillary tip may be optionally reformed with an additional step using the standard EFO wand to produce a larger sized FAB without the formation of undesirable metallurgical characteristics within the wire caused by the laser, plasma jet, or hydrogen flameoff in FIG. 9C.

### EXAMPLE

FIG. 10 discloses an array of straight vertical wire bonds with FABs 53, thermosonic bonded to the pixel readout pads 14 of substrate or ASIC readout IC 12. Since the bonding head and capillary travel only in a vertical direction when fabricating the straight vertical wire bonds 53, the wires have more precise X and Y-axis positioning accuracy than the prior art “modified” straight vertical wire bonds 52. In addition, the straight vertical wire bonds 53 terminate with FABs that provide an “anchor” when enclosed within ICA bumps 22 or solder bumps 18, as shown in FIG. 11. In addition, and of significant importance, this “new” vertical wire bonding process with fewer steps does not require the wire to be “crimped” against the surface of the substrate 12, or the extra processing steps to protect this surface with a photo resist and/or metal coating 17. FIG. 11 then illustrates the preferred assembly of a sensor or detector 2 onto a substrate 12. that includes the inventive vertical wire bonds with FABs shown in FIG. 10. This preferred assembly includes all the advantages as previously described and noted above and enables the use of copper wire, since the tips terminate in a spherical ball that is less likely to damage the fragile pads of many sensors and detectors.

### EXAMPLE

FIG. 11 also illustrates how the Cathode's high voltage biasing contact can be implemented using a similar straight vertical wire bonding process as for the anode pads on the substrate. Attached to the a high voltage biasing pad 19 is a much taller straight vertical wire bond 53 that has been manually formed to bring the FAB to touch the surface of the Cathode 4. The FAB is attached in place using ICA adhesive 22 (not shown) to make electrical connection from pad 19 to the surface of the Cathode. A typical biasing voltage is 500V; therefore multiple long straight vertical wire bonds 53 may be required for this application.

It should be noted that, although a fiber optic laser, plasma jet, or hydrogen flame is the preferred means or method to simultaneously cut the wire and form a FAB on both ends of the cut wires, other means may be employed to produce vertical wire bonds without the necessity for looping and “crimping” the wire against the surface of a substrate. For instance, the power of the fiber optic laser may be intentionally reduced to only weaken the wire at a point to be broken when the wire is pulled taught by the closed clamp. Alternatively, the wire may be crimped in situ by means of a clamp that includes bladed edges and which is positioned below the tip of the capillary and programmed to perform the crimping step at the proper point in the vertical wire forming process. In addition, an Electronic Flame Off (EFO) wand may be used to form an FAB at both ends of the cut wires, if a grounding clamp or wand is used to shunt the EFO voltage/current from damaging static sensitive devices connected to the substrate or ASIC readout pads.

### EXAMPLE

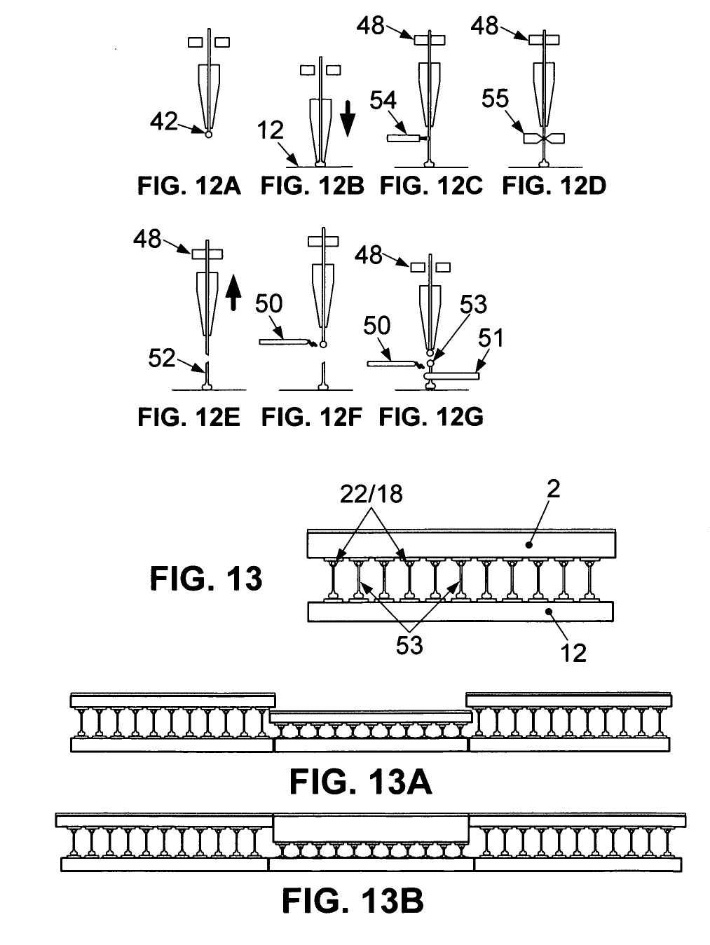

FIG. 12 discloses alternative steps for fabricating a straight vertical wire bond with FAB 53, or without FAB 52, in fewer steps than the prior art “modified” straight vertical wire bonding process:
1. The bonding cycle begins with the FAB 42 pre-formed at the end of the gold or copper wire protruding from the tip of the capillary and the wire clamp open (FIG. 12A).
2. The wire clamp remains opens and the bonding head moves the capillary tip into position over substrate 12 before dropping down against the substrate pad with sufficient force, ultrasonic scrubbing energy, and heat from the substrate to cause the FAB to deform and make a ball bond to the surface of the substrate (FIG. 12B).
3. With the wire clamp 48 remaining open, the bonding head raises the capillary as wire is paid out until the tip reaches the correct height for forming the vertical wire bond. At this point, the clamp closes and a laser beam, plasma jet, or hydrogen flame 54 intersects the wire and cuts or only weakens the wire (FIG. 12C).
4. Alternatively, a bladed clamp 55, positioned below the tip of the capillary, closes and crimps the wire in situ (FIG. 12D).
5. With the clamp 48 still closed, the bonding head raises the capillary and breaks the weakened wire, leaving a straight vertical wire bond without FAB 52 attached to the substrate (FIG. 12E).
6. The bonding head moves to a higher position to actuate the EFO wand, forming a FAB at the tip of the wire protruding from the capillary. At this point the bonding head would repeat steps 1-6 to form an array of straight vertical wire bonds without FABs 52 (FIG. 12F).
7. Alternatively, the clamp opens and the FAB is drawn with air tension against the tip of the capillary. The bonding head descends to bring the EFO wand to the proper position to form an FAB at the tip of the straight vertical wire bond 52 that was formed in step 5. An EFO shunt 51 moves to contact the straight vertical wire 52 before the EFO is actuated, protecting ESD sensitive devices as the EFO discharges to form a straight vertical wire bond with FAB 53. The bonding head then proceeds to the next bonding site and repeats steps 1-7 (FIG. 12G).

It should be noted that in forming straight vertical wire bonds with FABs 53 on most substrates 12 and interposers 36, as shown for example in FIG. 4, that an EFO shunt 51 would not be required to touch the vertical wire 52 when actuating the EFO, since the pads would not be connected to active circuitry that may be damaged by the EFO's voltage/current pulse. And, if the ASIC chip pads include an internal means for protecting the chip from electrostatic discharge (ESD), then the shunt may not be required. EFO shunt 51 may be connected directly to a an electrical ground or to the EFO Control Box (not shown) for monitoring the voltage or current level on the shunt to determine if the EFO wand failed to supply the energy necessary to form an FAB on the tip of the wire. Also, instead of a shunt directly to ground, the voltage may be dissipated through a resistor of high value for safety purposes. It should also be noted that various other means besides a laser beam, plasma jet, or hydrogen flame 54, or bladed clamp 55, may be adapted to weaken the wire in step 3 or 4 above.

Tiled Detectors Using Vertical Wire Bonds

### EXAMPLE

FIG. 13 represents a preferred assembly of a sensor or detector 2 flip chip bonded, using ICA adhesive bumps 22 or solder paste bumps 18, to an array of straight vertical wire bonds with FABs 53 on substrate or ASIC readout chip 12. Varying the height of the array of vertical wire bonds, the detectors can be tiled in two unique ways. In the example shown in FIG. 13A the edges of the adjacent detectors overlap enabling the pixel pitch to be maintained across the length of the tiled array. In FIG. 13B, detectors with different thickness are tiled edge-to-edge with their Cathode surfaces planar to one another.

Realigning Bent Vertical Wire Bonds

### EXAMPLE

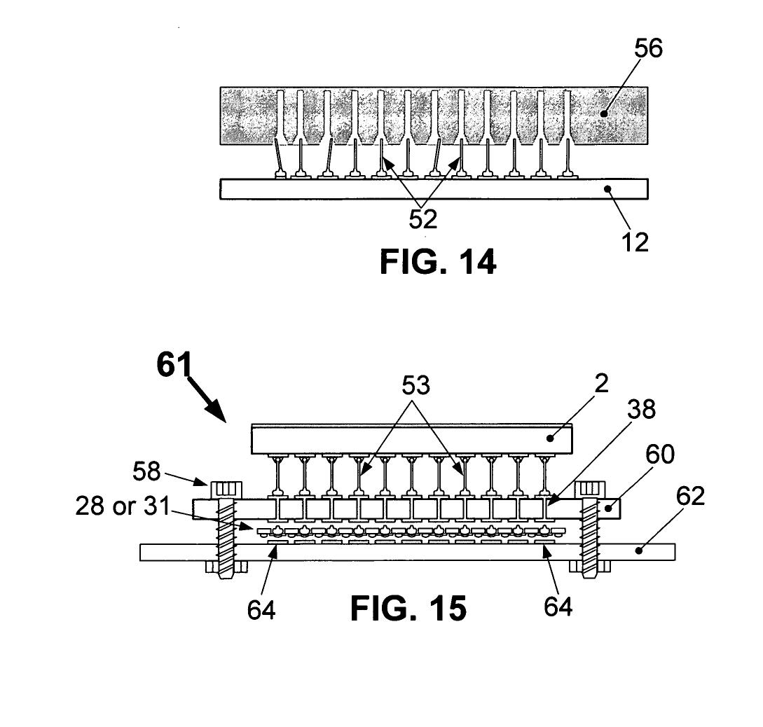

Turning now to FIG. 14, a method for straightening bent or misaligned vertical wire bonds is disclosed. Substrate 12 is similar to FIG. 8A and includes an area array of vertical wire bonds without FABs 52, some of which are bent out-of-alignment. It is expected that in the process of handling these types of substrates, that the vertical wire bonds shall occasionally be bent out-of-alignment, and that a simple method for re-aligning the wires is desirable. Using an alignment fixture 56, with tapered openings on the same pitch as the array of vertical wire bonds 52, the pins may be brought back into alignment as the fixture is brought close to contact with the surface of substrate 12. Although, it is feasible to encapsulate the array of vertical wire bonds using a plastic molding process to permanently fix the wires in their proper aligned positions, this would eliminate several advantages already described above, and is therefore not a preferred method or design for the assembly of many types of sensors and detectors. The alignment fixture 56 may be fashioned from a variety of plastic materials by drilling or molding the required tapered openings and straight walls at the correct pitch for the particular area array of vertical wire bonds. Using a manual flip chip bonder with the fixture held with its tapered holes facing down, the fixture would be lowered onto the pins after performing a visual alignment using a split-field prism with camera optics.

Examples of Removable Assemblies Using Compression Decals

### EXAMPLE

FIG. 15 combines elements from FIG. 3A (not shown), or FIG. 3C and FIG. 13 to illustrate one example of a removable assembly 61 with corner compression posts. Detector 2 is attached to a ceramic interposer 60 by means of straight vertical wire bonds with FABs 53 using ICA adhesive bumps. Sandwiched between the interposer and printed circuit board (PCB) motherboard 62 is a compression decal 28 (not shown) or 31 (as shown) aligned with the bottom pads of the interposer and top PCB contact pads 64. Using threaded screws and nuts 58 to apply a clamping pressure, the digital and/or analog signals passing through the interposer are coupled to the PCB motherboard 62. This example illustrates one means for testing detectors mounted to a test interposer. Since the interposer is larger than the detector, this is not a preferred embodiment for tiled detector arrays.

### EXAMPLE

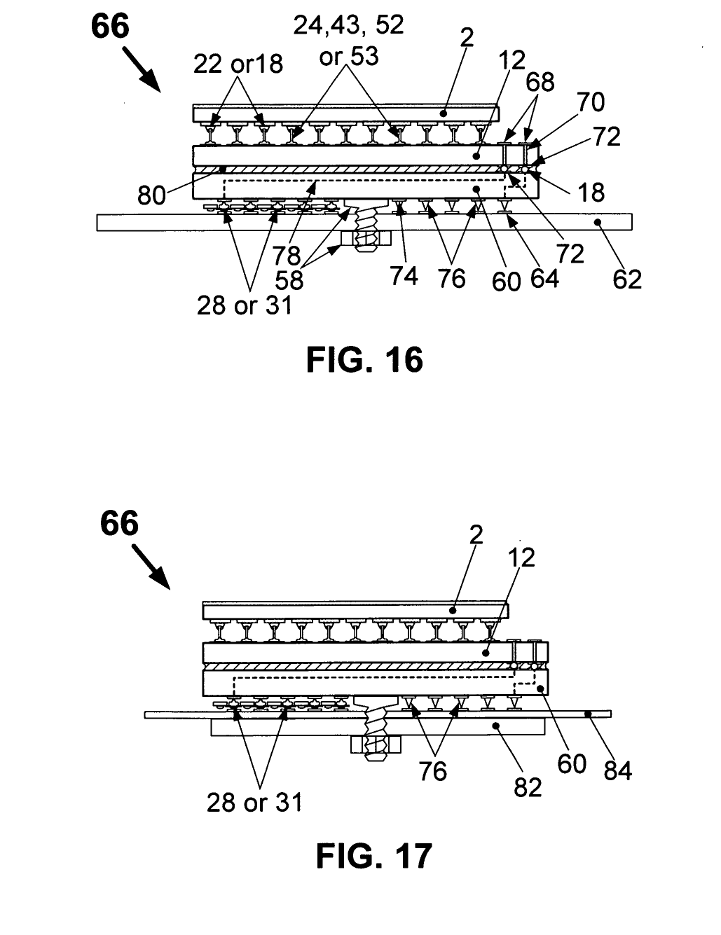

FIG. 16 is another example of a removable assembly with a single, center compression post 66. Detector 2 is attached to a silicon ASIC readout chip 12 with gold or copper stud bumps 24 (not shown), or leaning vertical wire bonds with FABs 43 (not shown), or straight vertical wire bonds without FABs 52 (not shown), or straight vertical wire bonds with FABs 53, as shown, that are bonded to an array of pixel readout pads. At one end of the ASIC chip are staggered wire bond pads 68. These pads are in turn electrically connected to flip chip pads 72 and solder balls 18 on the bottom surface of the chip by means of thru-silicon vias 70. The ASIC chip is in turn soldered at one end to a ceramic interposer 60, which has internal circuit traces 78 routed from pads 72 on its top surface, to compression contact pads 74 on the bottom surface of the interposer. The space between the ASIC chip and ceramic interposer is filled with and underfill epoxy 80 to help mitigate internal stress caused by a difference in thermal expansion between the silicon and ceramic. At the center of the ceramic interposer is a threaded screw (post) and nut 58 that is used to apply a downward compression force against a compression decal 28 or 31, sandwiched between and aligned with the bottom compression contact pads 74 of the interposer and the top contact pads 64 of the PCB motherboard 62. An alternative interposer contact, which is also suitable for compression mating with the pads on the PCB motherboard, consists of pointed contacts 76. This type of contact is integral (fixed) to the bottom contact pads 74 of the ceramic interposer, as shown, or to the top contact pads 64 of the PCB motherboard 62, and requires less force to achieve electrical conductivity with the pads on the motherboard. However, this type of contact is not as compliant across a range of temperatures as the compression decals 28 or 31, previously described.

A significant advantage for this type of removable detector assembly 66 is that the module can be readily removed and replaced from the motherboard when surrounded within a large cluster of multiple detectors with abutting edges. Typically, detector modules include one or more pinned connectors on the bottom surface that are inserted into sockets soldered to the top of the motherboard. The pin connectors and their mating sockets add considerable weight and height to the detector modules and make it extremely difficult to extract a module if it is closely surrounded by other modules. Detector assembly 66 is much simpler and easier to remove from within a cluster of tightly packed modules. Only the single compression nut on the bottom surface of the motherboard is removed, and a light force is applied to the protruding post, to push the module carefully upward. The module is then grasped by the edges and lifted free. The reverse procedure is used to replace a new module, after replacing the compression decal with a new one, if required.

### EXAMPLE

FIG. 17 illustrates a similar configuration of a removable detector assembly 66, as described in FIG. 16, with the exception that the PCB motherboard is replaced with a flexible circuit motherboard 84. This flexible circuit motherboard, may be a single, double or multilayer laminated circuit the same as a PCB motherboard, as is well known in the electronic industry. In this embodiment, a rigid metal or plastic stiffener plate 82, with approximately the same outer dimensions as the ceramic interposer 60, is positioned below the flexible motherboard and compresses against the bottom surface of the motherboard with sufficient force to enable the compression decal 28 or 31 or pointed contacts 76 to function properly.

### EXAMPLE

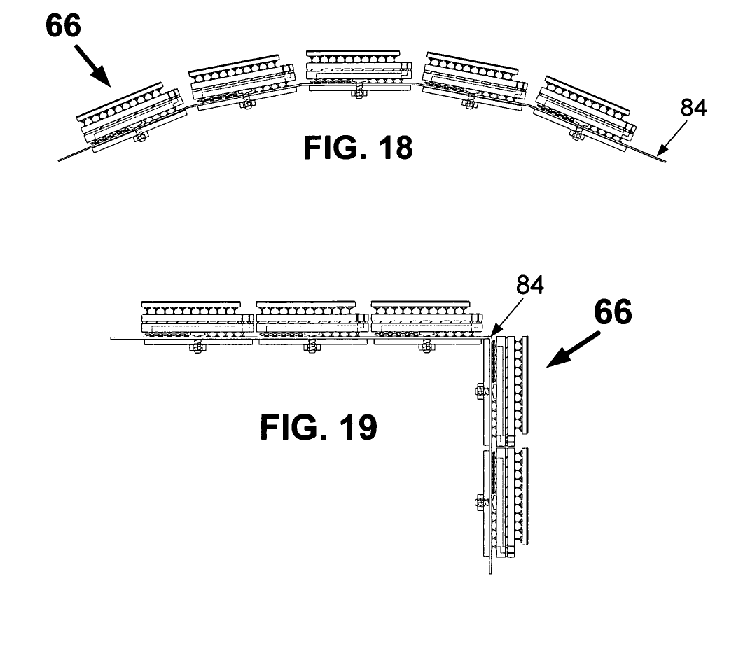

A significant advantage for the example of FIG. 17 is shown in FIG. 18 and FIG. 19. FIG. 18 shows multiple detector assemblies 66 interconnected on a flexible circuit motherboard 84 that are folded into an arch or circle (not shown), whereas FIG. 19 shows the detectors on the flexible circuit folded into a right angle or square (not shown). Each of these shapes may be optimized for arrays of sensors or detectors that require covering a specific field of view or direction of detection.

### EXAMPLE

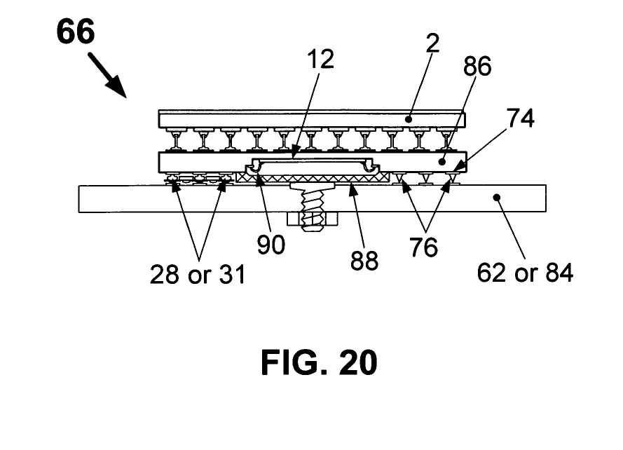

Another example of a removable detector assembly 66 is shown in FIG. 20. For some detector assemblies the ASIC readout chip 12 or other IC device may be smaller than the sensor or detector 2. In these assemblies the array of pixel pads on the detector spans a distance too large to interface directly to the ASIC chip. Therefore, a substrate or interposer in the form of a cavity-down chip carrier 86 is custom designed to receive the smaller ASIC readout chip 12, which is either die attached to the bottom of the cavity and wire bonded 90 to pads internal to the cavity, as shown, or flip chip bonded to pads underneath the ASIC chip (not shown) or die attached to the bottom surface without a cavity and wire bonded to pads on the same surface as used for die attach (not shown). A ceramic or metal cover 88 is designed to be firmly bonded over the cavity or surface of the chip carrier, protecting the fragile wire bonds and ASIC chip, while also providing an attachment surface for the compression screw or post 58. Since the cover transfers the force necessary to compress the compression decal 28 or 31 or pointed contacts 76 against the surface pads of the motherboard, the thickness of the cover must not impede the downward compression of the decal or pointed contacts. The cover must also be firmly attached to the perimeter of the cavity or bottom surface of the chip carrier to properly transfer the force of compression to the perimeter of the chip carrier. The compression screw or post may be brazed, soldered or epoxied to the surface of the cover, providing a sufficiently strong bond for applying the required compression force. The chip carrier is sized to enable the anode pads of the detector to connect directly to readout contact pads on the upper or top surface of the chip carrier, as previously described for substrate 12. However, the compression contact pads 74 of the chip carrier are placed in an array that is restricted to the outer perimeter of the bottom surface due to the presence of the cover. The resulting removable detector assembly is thinner and lighter weight than previous examples, but otherwise mates and interfaces to the PCB motherboard 62 or flexible circuit motherboard 84, as previously described.

It will be appreciated that the exemplary descriptions above are not intended to limit the applicability of the invention to those specific configurations or processes. For example, in any discussion of methods involving photolithography, it will be clear that either positive or negative photoresist systems may be used, and the skilled artisan can adapt the teachings herein to either system. The invention is not limited to specific semiconductor detector materials such as CdTe, CdZnTe (CZT), and TIBr, but rather may be adapted to virtually any detector having a similar configuration regardless of the particular semiconductor crystal used. Specific manufacturers and products have been cited where appropriate solely to provide examples of materials and processes that can be used by the artisan to fully understand and carry out the invention; the invention is not limited to these particular materials, products, and manufacturers.

### INDEX OF REFERENCE NUMERALS USED IN THE DRAWING FIGURES

2 Sensor or Detector

4 Cathode surface

6 Anode pixel pad

8 Detector guard-ring

9 Detector guard ring contact pad

10 Detector guard ring contact ribbon or strip

11 Inter-pixel gap

12 Substrate or ASIC readout device

14 Substrate or ASIC pixel readout pads

15 Substrate or ASIC guard ring contact pad

16 Indium metal bumps

17 Hardened photoresist and/or metal coating

18 Solder alloy balls or bumps

19 High voltage (Cathode) biasing pad

20 Anisotropic Conductive Adhesive (ACA) film or paste

22 Isotropic Conductive Adhesive (ICA) bumps

24 Gold or copper ball/stud bumps

26 Electrically conductive elastomeric connector film

28 ICA bumped compression decal

29 Contact adhesive dots

30 ICA filled via contacts

31 Ball/stud bumped compression decal

32 Thin copper pads with dimpled bottoms

34 Electrically conductive, UV-cured, ACA paste

36 Optically clear interposer or substrate

38 Conductive via interconnections

40 Gold coated surface

42 Free Air Balls (FABs)

43 Leaning vertical wire bond(s) with FAB

44 Gold wire

45 Wire forming tool

46 Ceramic wire bonding capillary

48 Wire clamp

50 Electronic Flame Off (EFO) wand

51 Electronic Flame Off (EFO) shunt

52 Straight vertical wire bond(s) without FAB

53 Straight vertical wire bond(s) with FAB

54 Fiber optic laser, plasma jet, or hydrogen flame

55 Bladed clamp

56 Alignment fixture

58 Clamping screw and nut

60 Ceramic interposer

61 Removable assembly with corner compression posts

62 Printed circuit board (PCB) motherboard

64 PCB contact pads

66 Removable assembly with center compression post

68 Wire bond pad

70 Thru-silicon via

72 Flip chip pad

74 Compression contact pad

76 Pointed contact

78 Internal circuit trace

80 Underfill epoxy

82 Stiffener plate

84 Flexible circuit motherboard

86 Cavity-down chip carrier

88 Ceramic or metal cover

90 Wire bond lead

I claim:

1. An imaging sensor comprising:
a first monolithic semiconductor plate having an upper surface and a lower surface;
a substantially continuous cathode deposited on said upper surface;
an array of anode pads on said lower surface, each anode pad defining an individual pixel;
a readout device having an array of readout pads on its upper surface, each readout pad corresponding to a respective anode pad and alignable therewith; and,
a plurality of parallel, vertical wire bonds interconnecting said semiconductor plate and said readout device, with each wire connecting one anode pad to its respective readout pad.

2. The imaging sensor of claim 1 wherein said readout device comprises a component selected from the group consisting of: substrates, interposers, and ASIC readout chips.

3. The imaging sensor of claim 1 wherein said wire bonds are connected to said anode pads using material selected from the group consisting of: isotropic conductive adhesives, and solder.

4. The imaging sensor of claim 1 wherein each of said vertical wires includes a Free Air Ball at its tip.

5. The imaging sensor of claim 1 further comprising at least a second semiconductor plate, wherein the wire bonds joining said anode pads of said first and second semiconductor plates to their respective readout pads are of different lengths to allow said first and second semiconductor plates to overlap so as to maintain a fixed pixel pitch across adjacent detector plates.

6. The imaging sensor of claim 1 further comprising at least a second semiconductor plate, having a different thickness from that of said first semiconductor plate, and a second readout device, and wherein the wire bonds joining said first and second semiconductor plates to their respective readout devices are of different lengths to allow said upper surfaces of said first and second semiconductor plates to be coplanar.

7. The imaging sensor of claim 1 further comprising:
an array of contact pads on the underside of said readout device;
a circuit board having an array of electrodes alignable with said contact pads;
a compression decal interposed between said contact pads and said electrodes and maintaining electrical continuity therebetween; and,
a means of applying a compressive force between said readout device and said circuit board

8. The imaging sensor of claim 7 wherein said circuit board is selected from the group consisting of: rigid circuit boards and flexible circuits.

9. The imaging sensor of claim 8 wherein said circuit board comprises a flexible circuit, a plurality of said imaging sensors are mounted thereto, and said flexible circuit is formed into a selected shape so that at least two of said plurality of imaging sensors are not coplanar with one another.

10. The imaging sensor of claim 9 wherein said selected shape is selected from the group consisting of: arcs, curved sections, cylinders, spheres, and planar sections intersecting at a selected angle.

11. An imaging sensor comprising:
a first monolithic semiconductor plate having an upper surface and a lower surface;
a cathode deposited on said upper surface in the form of independently-biased strips;
an array of anode pads arranged in rows on said lower surface with said rows running in a direction perpendicular to the long dimension of said cathode strips, so that the intersection of one cathode strip and one row of anode pads defines an individual pixel;
a readout device having an array of readout pads on its upper surface, each readout pad corresponding to a respective anode pad and alignable therewith; and,
a plurality of parallel, vertical wire bonds interconnecting said semiconductor plate and said readout device, with each wire connecting one anode pad to its respective readout pad.

12. The imaging sensor of claim 11 wherein said readout device comprises a component selected from the group consisting of: substrates, interposers, and ASIC readout chips.

13. The imaging sensor of claim 11 wherein said wire bonds are connected to said anode pads using material selected from the group consisting of: isotropic conductive adhesives, and solder.

14. The imaging sensor of claim 11 wherein each of said vertical wires includes a Free Air Ball at its tip.

15. The imaging sensor of claim 11 further comprising at least a second semiconductor plate, wherein the wire bonds joining said anode pads of said first and second semiconductor plates to their respective readout pads are of different lengths to allow said first and second semiconductor plates to overlap so as to maintain a fixed pixel pitch across adjacent detector plates.

16. The imaging sensor of claim 11 further comprising at least a second semiconductor plate, having a different thickness from that of said first semiconductor plate, and a second readout device, and wherein the wire bonds joining said first and second semiconductor plates to their respective readout devices are of different lengths to allow said upper surfaces of said first and second semiconductor plates to be coplanar.

17. The imaging sensor of claim 11 further comprising:
an array of contact pads on the underside of said readout device;
a circuit board having an array of electrodes alignable with said contact pads;
a compression decal interposed between said contact pads and said electrodes and maintaining electrical continuity therebetween; and,
a means of applying a compressive force between said readout device and said circuit board

18. The imaging sensor of claim 17 wherein said circuit board is selected from the group consisting of: rigid circuit boards and flexible circuits.

19. The imaging sensor of claim 18 wherein said circuit board comprises a flexible circuit, a plurality of said imaging sensors are mounted thereto, and said flexible circuit is formed into a selected shape so that at least two of said plurality of imaging sensors are not coplanar with one another.

20. The imaging sensor of claim 19 wherein said selected shape is selected from the group consisting of: arcs, curved sections, cylinders, spheres, and planar sections intersecting at a selected angle.
